(19) United States
(12) Patent Application Publication
(10) Pub. No.: US 2024/0258205 A1
(43) Pub. Date: Aug. 1, 2024

(54) INTEGRATED CIRCUIT DEVICE

(71) Applicant: SAMSUNG ELECTRONICS CO., LTD., SUWON-SI (KR)

(72) Inventors: Hoyun Jeon, SUWON-SI (KR); Seungyong Yoo, SUWON-SI (KR)

(21) Appl. No.: 18/498,020

(22) Filed: Oct. 30, 2023

(30) Foreign Application Priority Data
Jan. 27, 2023 (KR) 10-2023-0011117

(51) Int. Cl. H01L 23/48; H01L 27/088; H01L 29/06; H01L 29/423; H01L 29/66; H01L 29/775; H01L 29/786

(52) U.S. Cl. CPC H01L 23/481; H01L 27/088; H01L 29/0673; H01L 29/42392; H01L 29/66439; H01L 29/775; H01L 29/78696

(57) ABSTRACT

An integrated circuit device includes a lower insulating structure disposed over a substrate, a lower wiring structure that passes through the lower insulating structure in a vertical direction, an upper insulating structure disposed on the lower insulating structure, and an upper wiring structure that passes through the upper insulating structure in the vertical direction and contacts the lower wiring structure. The upper wiring structure includes an upper metal plug and an upper conductive barrier structure that surrounds a sidewall and a lower surface of the upper metal plug. The upper conductive barrier structure includes a first barrier portion that faces a sidewall of the upper insulating structure, and a second barrier portion interposed between the lower wiring structure and the upper metal plug. The first barrier portion and the second barrier portion have different structures from each other.

### CROSS-REFERENCE TO RELATED APPLICATION

This application claims priority under 35 U.S.C. § 119 from Korean Patent Application No. 10-2023-0011117, filed on Jan. 27, 2023 in the Korean Intellectual Property Office, the contents of which are herein incorporated by reference in their entirety.

### TECHNICAL FIELD

Embodiments of inventive concept are directed to an integrated circuit device, and more particularly, to an integrated circuit device that includes a metal wiring layer.

### DISCUSSION OF THE RELATED ARTR

Due to advances in electronics technology, integrated circuit devices have been rapidly down-scaled, and the line widths and pitches of metal wiring layers in integrated circuit devices also have been fine-sized. Therefore, the electrical reliability of metal wiring layers can be improved by suppressing the resistance increase and leakage current of metal wiring layers and suppressing the electromigration of metals.

### SUMMARY

Embodiments of the inventive concept provide an integrated circuit device that increases the electrical reliability of metal wiring layers thereof by suppressing a resistance increase and leakage current of the metal wiring layers and suppressing the electromigration of metals.

According to an embodiments of the inventive concept, there is provided an integrated circuit device that includes a lower insulating structure disposed over a substrate, a lower wiring structure that passes through the lower insulating structure in a vertical direction, an upper insulating structure disposed on the lower insulating structure, and an upper wiring structure that passes through the upper insulating structure in the vertical direction and contacts the lower wiring structure. The upper wiring structure includes an upper metal plug and an upper conductive barrier structure, where the upper conductive barrier structure surrounds a sidewall and a lower surface of the upper metal plug. The upper conductive barrier structure includes a first barrier portion that faces a sidewall of the upper insulating structure, and a second barrier portion interposed between the lower wiring structure and the upper metal plug. The first barrier portion and the second barrier portion have different structures from each other.

According to another embodiment of the inventive concept, there is provided an integrated circuit device that includes a lower insulating structure disposed over a substrate, a lower wiring structure that passes through the lower insulating structure in a vertical direction, an upper insulating structure disposed on the lower insulating structure, and an upper wiring structure that includes an upper metal plug that passes through the upper insulating structure in the vertical direction, and an upper conductive barrier structure that surrounds a sidewall and a lower surface of the upper metal plug. The upper conductive barrier structure includes a first barrier portion that is arranged between the upper metal plug and the upper insulating structure and contacts each of the upper metal plug and the upper insulating structure, and that includes a plurality of metal nitride films and a plurality of metal films, where the plurality of metal films including different metals from each other, and a second barrier portion that is arranged between the upper metal plug and the lower wiring structure and contacts each of the upper metal plug and the lower wiring structure, where the second barrier portion has a different structure from the first barrier portion.

According to yet another embodiment of the inventive concept, there is provided an integrated circuit device that includes a lower insulating structure disposed over a substrate, a lower wiring structure that passes through the lower insulating structure in a vertical direction, an upper insulating structure disposed on the lower insulating structure and the lower wiring structure and that includes an etch stop film and an interlayer dielectric that covers an upper surface of the etch stop film, where the etch stop film has a multilayered structure that includes a plurality of insulating films that include different materials from each other, and an upper wiring structure that includes an upper metal plug that passes through the upper insulating structure in the vertical direction, and an upper conductive barrier structure that surrounds a sidewall and a lower surface of the upper metal plug. The upper conductive barrier structure includes a first multilayered film that extends along a first sidewall of the upper insulating structure and includes a first TaN film, an Ru film, and a second TaN film that are sequentially stacked in the stated order from the first sidewall of the upper insulating structure toward the upper metal plug, where the first sidewall faces the upper wiring structure, and a second multilayered film that is disposed over the first sidewall of the upper insulating structure and extends along the first multilayered film and that is disposed on the lower wiring structure and extends along an upper surface of the lower wiring structure, where the second multilayered film is spaced apart from the first sidewall of the upper insulating structure with the first multilayered film interposed therebetween, and includes a third TaN film and a Co film that are sequentially stacked in the stated order from each of a surface of the first multilayered film and the upper surface of the lower wiring structure toward the upper metal plug.

### BRIEF DESCRIPTION OF THE DRAWINGS

FIG. 1A is a schematic cross-sectional view of an integrated circuit device according to some embodiments.

FIG. 1B is an enlarged cross-sectional view of a region EX1 of FIG. 1A.

FIG. 2 is a schematic cross-sectional view of an integrated circuit device according to some embodiments.

FIG. 3A is a schematic cross-sectional view of an integrated circuit device according to some embodiments.

FIG. 3B is an enlarged cross-sectional view of a region EX3 of FIG. 3A.

FIG. 4 is a schematic cross-sectional view of an integrated circuit device according to some embodiments.

FIG. 5A illustrates an integrated circuit device according to some embodiments.

FIG. 5B is a cross-sectional view of an integrated circuit device, taken along a line X1-X1′ of FIG. 5A.

FIG. 5C is a cross-sectional view of an integrated circuit device, taken along a line Y1-Y1′ of FIG. 5A.

FIGS. 6, 7, 8A, 9A, 10A, 11A, 12A, 13, and 14 are cross-sectional views that respectively illustrate a method of fabricating an integrated circuit device, according to some embodiments, and FIGS. 8B, 9B, 10B, 11B, and 12B are enlarged cross-sectional views of regions EX1 of FIGS. 8A, 9A, 10A, 11A, and 12A, respectively.

FIG. 15 is a cross-sectional view that illustrates a method of fabricating an integrated circuit device according to some embodiments.

FIGS. 16A and 17A are cross-sectional views that respectively illustrate a method of fabricating an integrated circuit device, according to some embodiments, and FIGS. 16B and 17B are enlarged cross-sectional views of regions EX3 of FIGS. 16A and 17A, respectively.

### DETAILED DESCRIPTION

Hereinafter, embodiments of the inventive concept will be described in detail with reference to the accompanying drawings. Like components may be denoted by like reference numerals throughout the specification, and repeated descriptions thereof are omitted.

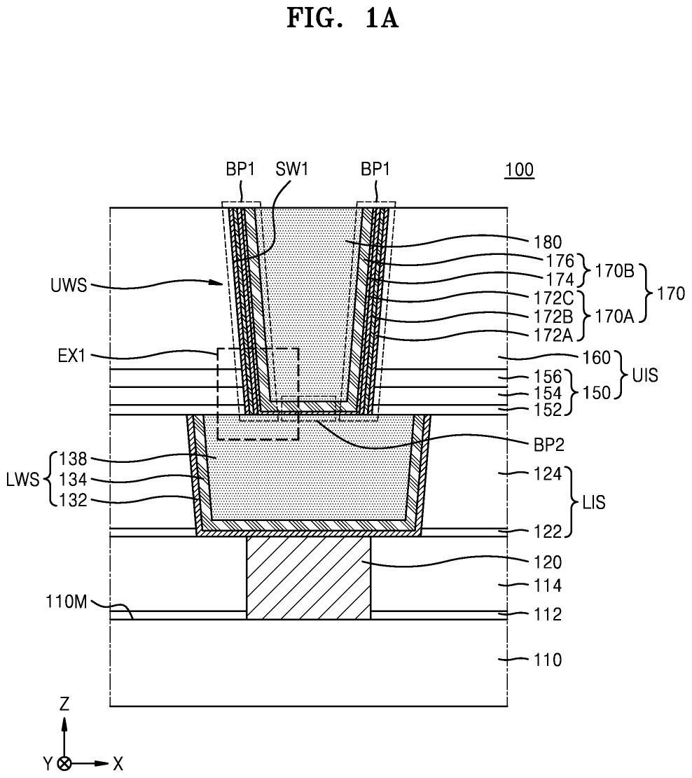

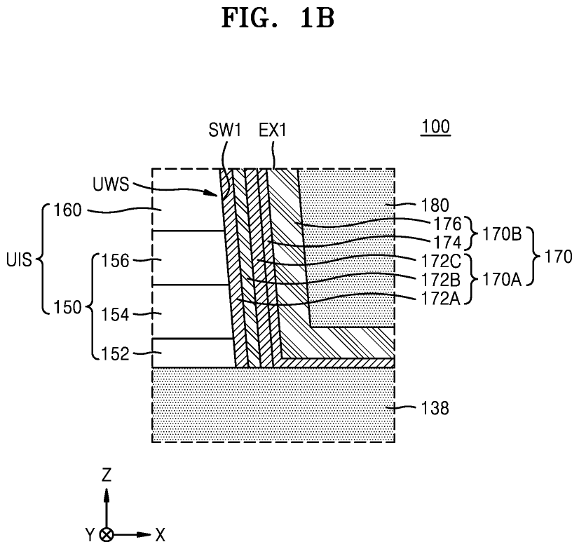

FIG. 1A is a schematic cross-sectional view of an integrated circuit device 100 according to some embodiments. FIG. 1B is an enlarged cross-sectional view of a region EX1 of FIG. 1A.

Referring to FIGS. 1A and 1B, in an embodiment, the integrated circuit device 100 includes a lower insulating structure LIS disposed over a substrate 110, a lower wiring structure LWS that passes through the lower insulating structure LIS in a vertical direction (Z direction), an upper insulating structure UIS disposed on the lower insulating structure LIS and the lower wiring structure LWS, and an upper wiring structure UWS that passes through the upper insulating structure UIS in the vertical direction (Z direction) and contacts the lower wiring structure LWS.

The substrate 110 may include a semiconductor, such as Si or Ge, or a compound semiconductor, such as SiGe, SiC, GaAs, InAs, or InP. The substrate 110 may include a conductive region. The conductive region may include an impurity-doped well, an impurity-doped structure, or a conductive layer. The substrate 110 includes circuit elements (not shown), such as a gate structure, an impurity region, a contact plug, etc.

A first etch stop film 112 and a first interlayer dielectric 114 are disposed on the substrate 110, and a conductive structure 120 is disposed on the substrate 110 and passes through the first interlayer dielectric 114 and the first etch stop film 112.

The first etch stop film 112 includes a material that has a different etch selectivity from the first interlayer dielectric 114. For example, the first etch stop film 112 includes one of a silicon nitride film, a carbon-doped silicon nitride film, or a carbon-doped silicon oxynitride film. In some embodiments, the first etch stop film 112 includes a metal nitride film, such as an AlN film.

In some embodiments, the first interlayer dielectric 114 includes a silicon oxide film. For example, the first interlayer dielectric 114 includes a silicon oxide-based material, such as at least one of a plasma-enhanced oxide (PEOX), tetraethyl orthosilicate (TEOS), boro-TEOS (BTEOS), phosphorous TEOS (PTEOS), boro-phospho-TEOS (BPTEOS), boro-silicate glass (BSG), phospho-silicate glass (PSG), or boro-phospho-silicate glass (BPSG), etc. In some embodiments, the first interlayer dielectric 114 includes a low-K film that has a low dielectric constant (that is, K) of about 2.2 to about 3.0, such as an SiOC film or an SiCOH film.

The conductive structure 120 includes a wiring layer that includes a metal film and a conductive barrier film that surrounds the metal film. The metal film includes at least one of Cu, W, Al, or Co. The conductive barrier film includes one of Ta, TaN, Ti, TiN, or a combination thereof. In some embodiments, the conductive structure 120 is electrically connected with a conductive region formed in the substrate 110. In some embodiments, the conductive structure 120 is connected to a source/drain region or a gate electrode of a transistor formed in the substrate 110.

The lower insulating structure LIS includes a second etch stop film 122 and a second interlayer dielectric 124 that are sequentially stacked in the stated order on the first interlayer dielectric 114. Constituent materials of the second etch stop film 122 and the second interlayer dielectric 124 are substantially similar to those of the first etch stop film 112 and the first interlayer dielectric 114, respectively.

The lower wiring structure LWS include a lower metal plug 138, and a first conductive barrier film 132 and a second conductive barrier film 134 that surround a sidewall and a lower surface of the lower metal plug 138. The first conductive barrier film 132 and the second conductive barrier film 134 constitute a lower conductive barrier structure. In some embodiments, the lower metal plug 138 includes one of Cu, W, Al, or Co. For example, the lower metal plug 138 includes Cu. In some embodiments, each of the first conductive barrier film 132 and the second conductive barrier film 134 includes one of a TaN film, a Co film, or a combination thereof. For example, the first conductive barrier film 132 includes a TaN film, and the second conductive barrier film 134 includes a Co film, but embodiments of the inventive concept are not necessarily limited thereto.

The upper insulating structure UIS is disposed on the second interlayer dielectric 124 and the lower wiring structure LWS. The upper insulating structure UIS includes a third etch stop film 150 that has a multilayered structure that includes a plurality of insulating films, and a third interlayer dielectric 160 that covers an upper surface of the third etch stop film 150.

In some embodiments, the third etch stop film 150 includes a first aluminum-containing insulating film 152, an SiOC film 154, and a second aluminum-containing insulating film 156. The SiOC film 154 covers an upper surface of the first aluminum-containing insulating film 152, and the second aluminum-containing insulating film 156 covers an upper surface of the SiOC film 154. In some embodiments, each of the first aluminum-containing insulating film 152 and the second aluminum-containing insulating film 156 includes one of an aluminum oxide film, an aluminum nitride film, or a combination thereof. For example, each of the first aluminum-containing insulating film 152 and the second aluminum-containing insulating film 156 includes an aluminum oxide film.

The thicknesses of the first aluminum-containing insulating film 152 and the second aluminum-containing insulating film 156 in the vertical direction (Z direction) differ from each other. In some embodiments, the thickness of the first aluminum-containing insulating film 152 is greater than the thickness of the second aluminum-containing insulating film 156 in the vertical direction (Z direction). In some embodiments, the thickness of the first aluminum-containing insulating film 152 is less than or equal to the thickness of the second aluminum-containing insulating film 156 in the vertical direction (Z direction).

A constituent material of the third interlayer dielectric 160 is substantially similar to that of the first interlayer dielectric 114, which is described above. For example, the third interlayer dielectric 160 includes a silicon oxide film.

The upper wiring structure UWS includes an upper metal plug 180 that passes through the upper insulating structure UIS in the vertical direction (Z direction), and an upper conductive barrier structure 170 that surrounds a sidewall and a lower surface of the upper metal plug 180. In some embodiments, the upper metal plug 180 includes at least one of Cu, W, Al, or Co. For example, the upper metal plug 180 includes Cu.

In some embodiments, the upper conductive barrier structure 170 of the upper wiring structure UWS includes a first multilayered film 170A and a second multilayered film 170B that are sequentially stacked in the stated order from the upper insulating structure UIS toward the upper metal plug 180. The first multilayered film 170A and the second multilayered film 170B have different stacked structures from each other.

The first multilayered film 170A extends along a sidewall SW1 of the upper insulating structure UIS that faces the upper wiring structure UWS. For example, the sidewall SW1 that faces the upper wiring structure UWS may be referred to as a first sidewall. The first multilayered film 170A includes a first TaN film 172A, an Ru film 172B, and a second TaN film 172C that are sequentially stacked in the stated order from the sidewall SW1 of the upper insulating structure UIS toward the upper metal plug 180. A main surface of each of the first TaN film 172A, the Ru film 172B, and the second TaN film 172C of the first multilayered film 170A does not cover an upper surface of the lower wiring structure LWS. For example, a main surface of a component refers to a surface that has a relatively larger surface area than other surfaces of the component. For example, a main surface of the first multilayered film 170A refers to a surface that is perpendicular to a stacking direction of the first TaN film 172A, the Ru film 172B, and the second TaN film 172C of the first multilayered film 170A, and the main surface of each of the first TaN film 172A, the Ru film 172B, and the second TaN film 172C refers to a surface that is parallel to the main surface of the first multilayered film 170A. In some embodiments, each of the first TaN film 172A, the Ru film 172B, and the second TaN film 172C have, but are not necessarily limited to, a thickness of about 10 Å to about 15 Å. For example, the thickness of each of the first TaN film 172A, the Ru film 172B, and the second TaN film 172C refers to the size in a direction that is perpendicular to the main surface of each of the first TaN film 172A, the Ru film 172B, and the second TaN film 172C.

In some embodiments, each of the first TaN film 172A and the second TaN film 172C that constitute the first multilayered film 170A is formed by an atomic layer deposition (ALD) process and has a relatively low-density structure. For example, a portion of the Ru film 172B between the first TaN film 172A and the second TaN film 172C penetrates into the first TaN film 172A, and another portion of the Ru film 172B penetrates into the second TaN film 172C. Therefore, unlike the example shown in FIGS. 1A and 1B for convenience of illustration, a boundary line between the Ru film 172B and the first TaN film 172A and a boundary line between the Ru film 172B and the second TaN film 172C each have a irregularly curved shape rather than a straight line shape.

The second multilayered film 170B is disposed over the sidewall SW1 of the upper insulating structure UIS and extends along the first multilayered film 170A, and is also disposed on the lower wiring structure LWS and extends along the upper surface of the lower wiring structure LWS. The second multilayered film 170B is apart from the sidewall SW1 of the upper insulating structure UIS with the first multilayered film 170A therebetween. The second multilayered film 170B includes a third TaN film 174 and a Co film 176 that are sequentially stacked in the stated order from a surface of the first multilayered film 170A and the upper surface of the lower wiring structure LWS toward the upper metal plug 180. A main surface of each of the third TaN film 174 and the Co film 176 faces the sidewall SW1 of the upper insulating structure UIS and the upper surface of the lower wiring structure LWS. In some embodiments, the third TaN film 174 has a thickness of about 5 Å to about 10 Å, and the Co film 176 has a thickness of about 20 Å to about 30 Å. For example, the thickness of each of the third TaN film 174 and the Co film 176 refers to the size in a direction that is perpendicular to the main surface of each of the third TaN film 174 and the Co film 176.

The upper conductive barrier structure 170 of the upper wiring structure UWS includes a first barrier portion BP1 that is disposed between the upper insulating structure UIS and the upper metal plug 180 and faces the sidewall SW1 of the upper insulating structure UIS, and a second barrier portion BP2 disposed between the lower wiring structure LWS and the upper metal plug 180. The first barrier portion BP1 and the second barrier portion BP2 have different multilayered structures from each other. The first barrier portion BP1 includes the first multilayered film 170A and a portion of the second multilayered film 170B that is located between the upper insulating structure UIS and the upper metal plug 180. The second barrier portion BP2 does not include the first multilayered film 170A but includes a portion of the second multilayered film 170B that is interposed between the lower wiring structure LWS and the upper metal plug 180. Therefore, the thickness of the first barrier portion BP1 is greater than the thickness of the second barrier portion BP2.

In the upper conductive barrier structure 170, the first barrier portion BP1 includes at least three conductive films that differ from each other and are sequentially stacked from the upper insulating structure UIS toward the upper metal plug 180. For example, as shown in FIGS. 1A and 1B, the first barrier portion BP1 includes five conductive films, namely the first TaN film 172A, the Ru film 172B, the second TaN film 172C, the third TaN film 174, and the Co film 176 that are sequentially stacked in the stated order from the upper insulating structure UIS toward the upper metal plug 180. For example, the second TaN film 172C and the third TaN film 174 include the same material but have different densities from each other. For example, the second TaN film 172C is formed by an ALD process, and the third TaN film 174 is formed by a physical vapor deposition (PVD) process. Therefore, the density of the third TaN film 174 is greater than the density of the second TaN film 172C. In some embodiments, the boundary between the second TaN film 172C and the third TaN film 174 is unclear, and, for example, the second TaN film 172C and the third TaN film 174 appear to be one TaN film.

In the upper conductive barrier structure 170, the second barrier portion BP2 includes two conductive films that differ from each other and are sequentially stacked from the lower wiring structure LWS toward the upper metal plug 180. In the upper conductive barrier structure 170, the first barrier portion BP1 and the second barrier portion BP2 commonly include the two different conductive films. For example, as shown in FIGS. 1A and 1B, the second barrier portion BP2 includes the third TaN film 174 and the Co film 176 that are sequentially stacked in the stated order from the lower wiring structure LWS toward the upper metal plug 180. In the upper conductive barrier structure 170, the first barrier portion BP1 and the second barrier portion BP2 commonly include the third TaN film 174 and the Co film 176. The Ru film 172B of the first barrier portion BP1 is spaced apart from the Co film 176 with the second TaN film 172C and the third TaN film 174 therebetween.

In the upper conductive barrier structure 170, the main surface of the first TaN film 172A is in contact with the sidewall SW1 of the upper insulating structure UIS. In some embodiments, the main surface of the first TaN film 172A is in contact with each of the third etch stop film 150 and the third interlayer dielectric 160 that are included in the upper insulating structure UIS. The third TaN film 174 includes a portion that contacts the upper surface of the lower wiring structure LWS and a portion that contacts the main surface of the second TaN film 172C. The Co film 176 includes portions that respectively contact a sidewall and a lower surface of the upper metal plug 180 and are apart from the lower wiring structure LWS with the third TaN film 174 interposed therebetween.

As shown in FIG. 1A, the width of the lower wiring structure LWS is greater than the width of the upper wiring structure UWS in a first horizontal direction (X direction) that is parallel to a main surface 110M of the substrate 110. Therefore, the first barrier portion BP1 of the upper conductive barrier structure 170 is in contact with only the upper insulating structure UIS, not the lower insulating structure LIS.

The integrated circuit device 100 shown in FIGS. 1A and 1B includes the lower wiring structure LWS and the upper wiring structure UWS that are connected to each other, and the upper conductive barrier structure 170 that surrounds the upper metal plug 180 in the upper wiring structure UWS includes the first barrier portion BP1 that faces the sidewall SW1 of the upper insulating structure UIS, and the second barrier portion BP2 that faces the lower wiring structure LWS and has a different structure from the first barrier portion BP1. By minimizing the volume of a metal nitride film that has a resistance that is greater than that of a metal film in the second barrier portion BP2 that faces the lower wiring structure LWS, the contact resistance between the lower wiring structure LWS and the upper wiring structure UWS can be reduced. In addition, by enhancing barrier properties of the first barrier portion BP1, which faces the sidewall SW1 of the upper insulating structure UIS, by using a plurality of metal nitride films, such as the first TaN film 172A, the second TaN film 172C, and the third TaN film 174, unintended electromigration of a metal from the upper metal plug 180 can be suppressed and unintended impurity particles, such as oxygen atoms, can be prevented from penetrating from the upper insulating structure UIS into the upper metal plug 180. Furthermore, by inserting the Ru film 172B between two metal nitride films, such as the first TaN film 172A and the second TaN film 172C that are selected from the plurality of metal nitride films that constitute the first barrier portion BP1, the densities of the plurality of metal nitride films can be increased, and simultaneously, barrier properties of the plurality of metal nitride films can be enhanced. Therefore, the reliability of the integrated circuit device 100 that includes the upper wiring structure UWS is increased.

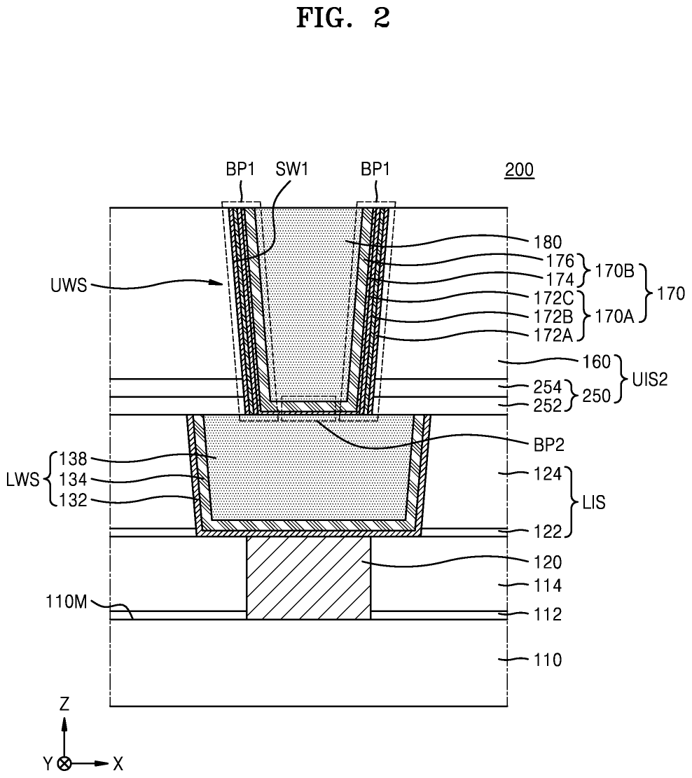

FIG. 2 is a schematic cross-sectional view of an integrated circuit device 200 according to some embodiments. In FIG. 2, the same reference numerals as in FIGS. 1A and 1B respectively denote the same members, and repeated descriptions thereof are omitted.

Referring to FIG. 2, in an embodiment, the integrated circuit device 200 has substantially the same configuration as the integrated circuit device 100 shown in FIGS. 1A and 1B. However, the integrated circuit device 200 includes an upper insulating structure UIS2 instead of the upper insulating structure UIS shown in FIGS. 1A and 1B.

The upper insulating structure UIS2 has substantially the same configuration as the upper insulating structure UIS described with reference to FIGS. 1A and 1B. However, the upper insulating structure UIS2 includes a third etch stop film 250 that has a double-layered structure, and the third interlayer dielectric 160 that covers an upper surface of the third etch stop film 250, where the third etch stop film 250 and the third interlayer dielectric 160 are sequentially stacked in the stated order on the second interlayer dielectric 124.

The third etch stop film 250 includes an aluminum-containing insulating film 252 and an SiOC film 254. The SiOC film 254 covers an upper surface of the aluminum-containing insulating film 252. The third interlayer dielectric 160 covers an upper surface of the SiOC film 254. In some embodiments, the aluminum-containing insulating film 252 includes one of an aluminum oxide film, an aluminum nitride film, or a combination thereof. For example, the aluminum-containing insulating film 252 includes an aluminum nitride film.

The upper wiring structure UWS passes through the third etch stop film 250 and the third interlayer dielectric 160 in the vertical direction (Z direction). In the upper conductive barrier structure 170 of the upper wiring structure UWS, the main surface of the first TaN film 172A is in contact with the sidewall SW1 of the upper insulating structure UIS2. In some embodiments, the main surface of the first TaN film 172A is in contact with each of the third etch stop film 250 and the third interlayer dielectric 160 that are included in the upper insulating structure UIS2.

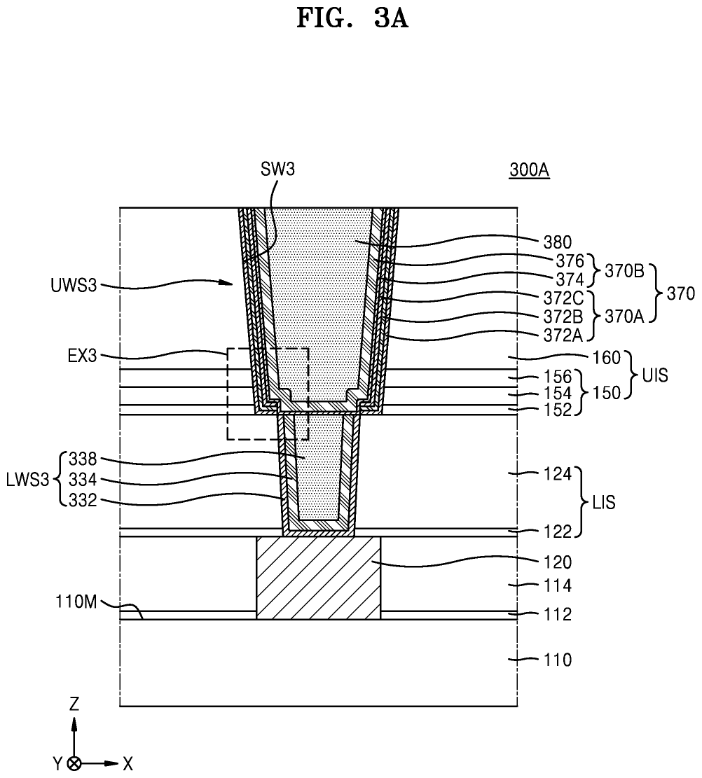

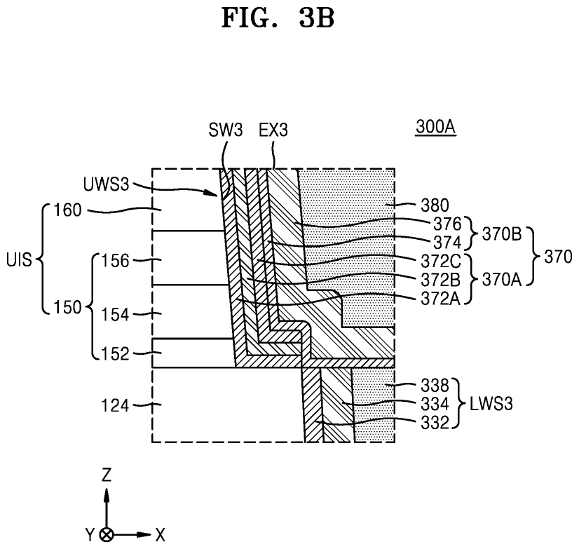

FIG. 3A is a schematic cross-sectional view of an integrated circuit device 300A according to some embodiments. FIG. 3B is an enlarged cross-sectional view of a region EX3 of FIG. 3A. In FIGS. 3A and 3B, the same reference numerals as in FIGS. 1A and 1B respectively denote the same members, and repeated descriptions thereof are omitted.

Referring to FIGS. 3A and 3B, in an embodiment, the integrated circuit device 300A has substantially the same configuration as the integrated circuit device 100 shown in FIGS. 1A and 1B. However, the integrated circuit device 300A includes the lower insulating structure LIS over the substrate 110, a lower wiring structure LWS3 that passes through the lower insulating structure LIS in the vertical direction (Z direction), the upper insulating structure UIS disposed on the lower insulating structure LIS and the lower wiring structure LWS3, and an upper wiring structure UWS3 that passes through the upper insulating structure UIS in the vertical direction (Z direction) and contacts the lower wiring structure LWS3.

The lower wiring structure LWS3 includes a lower metal plug 338, and a first conductive barrier film 332 and a second conductive barrier film 334 that surround a sidewall and a lower surface of the lower metal plug 338. The first conductive barrier film 332 and the second conductive barrier film 334 constitute a lower conductive barrier structure. In some embodiments, the lower metal plug 338 includes one or more of Cu, W, Al, or Co. For example, the lower metal plug 338 includes Cu. In some embodiments, each of the first conductive barrier film 332 and the second conductive barrier film 334 includes one of a TaN film, a Co film, or a combination thereof. For example, the first conductive barrier film 332 includes a TaN film, and the second conductive barrier film 334 includes a Co film, but embodiments of the inventive concept are not necessarily limited thereto.

The upper wiring structure UWS3 includes an upper metal plug 380 that passes through the upper insulating structure UIS in the vertical direction (Z direction), and an upper conductive barrier structure 370 that surrounds a sidewall and a lower surface of the upper metal plug 380. A detailed configuration of the upper metal plug 380 is substantially the same as that of the upper metal plug 180 described with reference to FIGS. 1A and 1B.

The upper conductive barrier structure 370 of the upper wiring structure UWS3 includes a first multilayered film 370A and a second multilayered film 370B that are sequentially stacked in the stated order from the upper insulating structure UIS toward the upper metal plug 380. The first multilayered film 370A and the second multilayered film 370B have different stacked structures from each other.

The first multilayered film 370A extends along a sidewall SW3 of the upper insulating structure UIS that faces the upper wiring structure UWS3. The first multilayered film 370A includes a first TaN film 372A, an Ru film 372B, and a second TaN film 372C that are sequentially stacked in the stated order from the sidewall SW3 of the upper insulating structure UIS toward the upper metal plug 380. The first TaN film 372A, the Ru film 372B, and the second TaN film 372C that are included in the first multilayered film 370A have substantially the same configurations as those of the first TaN film 172A, the Ru film 172B, and the second TaN film 172C described with reference to FIGS. 1A and 1B, respectively. However, the first TaN film 372A of the first multilayered film 370A is in contact with each of the lower insulating structure LIS and the upper insulating structure UIS.

The second multilayered film 370B is disposed over the sidewall SW3 of the upper insulating structure UIS and extends along the first multilayered film 370A, and is disposed on the lower wiring structure LWS3 and extends along an upper surface of the lower wiring structure LWS3. The second multilayered film 370B is spaced apart from the sidewall SW3 of the upper insulating structure UIS with the first multilayered film 370A therebetween. The second multilayered film 370B includes a third TaN film 374 and a Co film 376 that are sequentially stacked in the stated order from each of a surface of the first multilayered film 370A and the upper surface of the lower wiring structure LWS3 toward the upper metal plug 380. A main surface of each of the third TaN film 374 and the Co film 376 faces the sidewall SW3 of the upper insulating structure UIS and the upper surface of the lower wiring structure LWS3. The third TaN film 374 and the Co film 376 in the second multilayered film 370B have substantially the same configurations as those of the third TaN film 174 and the Co film 176 described with reference to FIGS. 1A and 1B

The width of the lower wiring structure LWS3 is less than the width of the upper wiring structure UWS3 in the first horizontal direction (X direction) parallel to the main surface 110M of the substrate 110. Therefore, in the upper conductive barrier structure 370, the first multilayered film 370A is in contact with each of the lower insulating structure LIS and the upper insulating structure UIS, while the second multilayered film 370B is not in contact with the lower insulating structure LIS or the upper insulating structure UIS but is in contact with respective upper surfaces of the lower metal plug 338, the first conductive barrier film 332, and the second conductive barrier film 334.

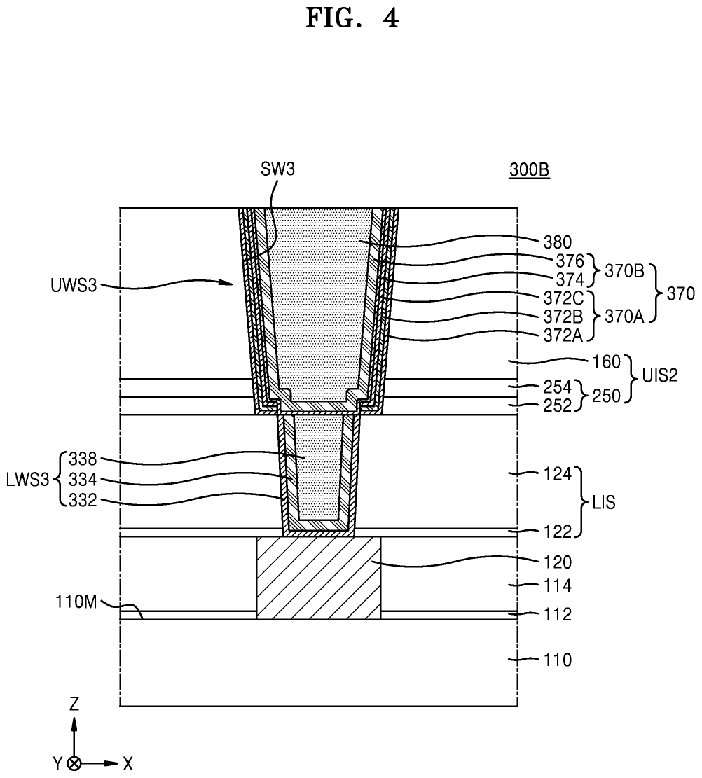

FIG. 4 is a schematic cross-sectional view of an integrated circuit device 300B according to some embodiments. In FIG. 4, the same reference numerals as in FIGS. 1A to 3B respectively denote the same members, and repeated descriptions thereof are omitted.

Referring to FIG. 4, in an embodiment, the integrated circuit device 300B has substantially the same configuration as the integrated circuit device 300A shown in FIGS. 3A and 3B. However, the integrated circuit device 300B includes the upper insulating structure UIS2 instead of the upper insulating structure UIS shown in FIGS. 3A and 3B. A detailed configuration of the upper insulating structure UIS2 is the same as that described with reference to FIG. 2.

The upper wiring structure UWS3 passes through the third etch stop film 250 and the third interlayer dielectric 160 in the vertical direction (Z direction). In the upper conductive barrier structure 370 of the upper wiring structure UWS3, the main surface of the first TaN film 372A is in contact with the sidewall SW3 of the upper insulating structure UIS2. In some embodiments, the main surface of the first TaN film 372A is in contact with the third etch stop film 250 and the third interlayer dielectric 160 of the upper insulating structure UIS2, and the second interlayer dielectric 124 of the lower insulating structure LIS.

Similar to the integrated circuit device 100 described with reference to FIGS. 1A and 1B, because each of the integrated circuit devices 200, 300A, and 300B shown in FIGS. 2 to 4 includes the upper conductive barrier structure 170 or 370 surrounding the upper metal plug 180 or 380 in the upper wiring structure UWS or UWS3, the contact resistance between the lower wiring structure LWS or LWS3 and the upper wiring structure UWS or UWS3 can be reduced, and the reliability of each of the integrated circuit devices 200, 300A, and 300B can be increased by suppressing unintended electromigration of a metal from the upper metal plug 180 or 380 and preventing unintended impurity particles, such as oxygen atoms, from penetrating into the upper metal plug 180 or 380 from the upper insulating structure UIS or UIS2.

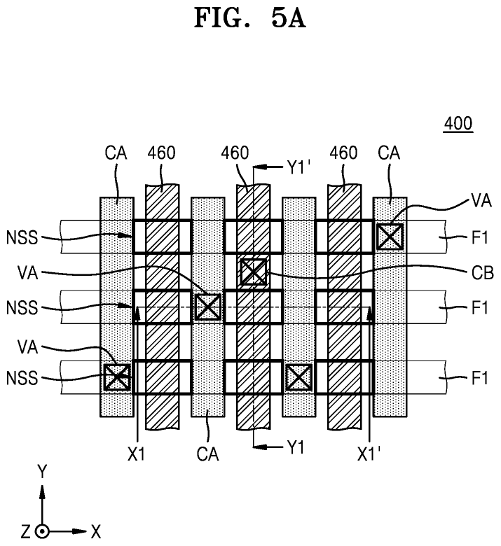

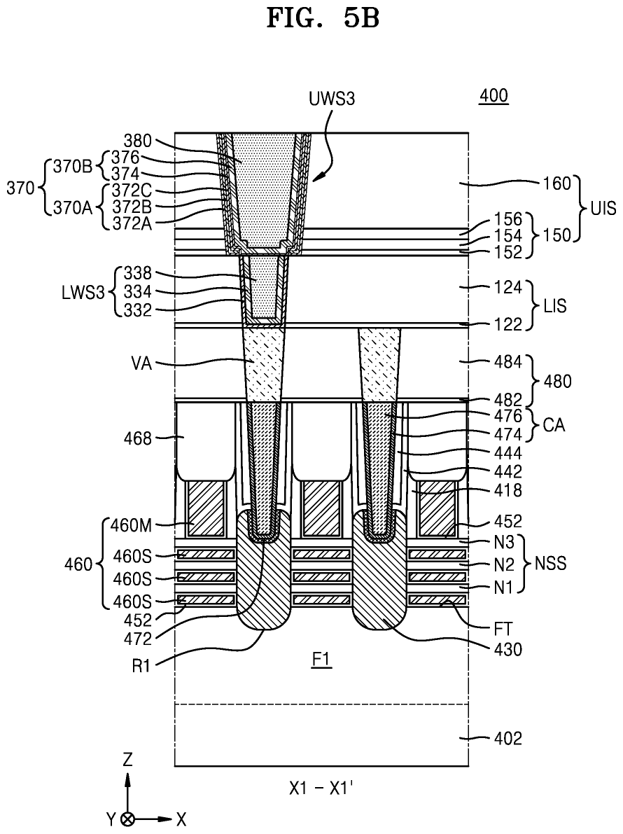

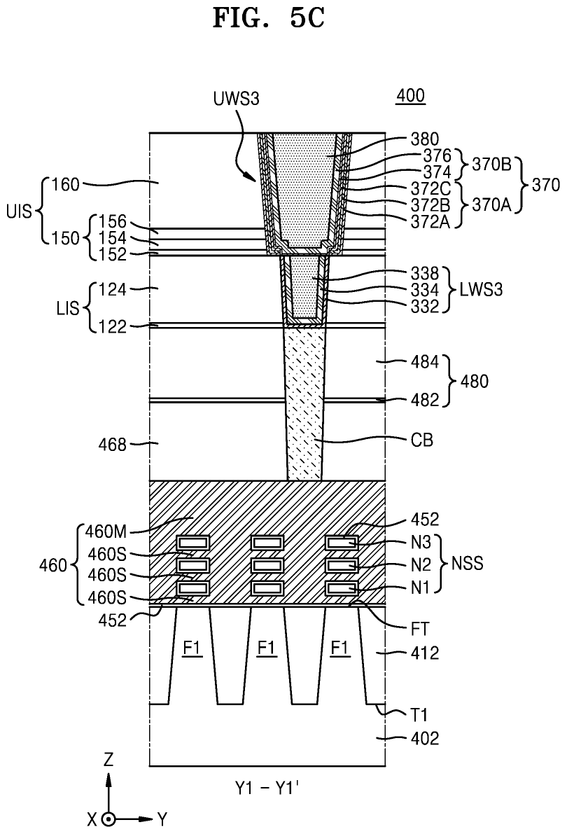

FIG. 5A illustrates an integrated circuit device 400 according to some embodiments. FIG. 5B is a cross-sectional view of the integrated circuit device 400, taken along a line X1-X1′ of FIG. 5A. FIG. 5C is a cross-sectional view of the integrated circuit device 400, taken along a line Y1-Y1′ of FIG. 5A. The integrated circuit device 400 includes a field-effect transistor that has a gate-all-around structure, which includes a nanowire or nanosheet-shaped active region and a gate that surrounds the active region, and is described with reference to FIGS. 5A to 5C. In FIGS. 5A to 5C, the same reference numerals as in FIGS. 1A to 4 respectively denote the same members, and repeated descriptions thereof are omitted.

Referring to FIGS. 5A to 5C, in an embodiment, the integrated circuit device 400 includes a plurality of fin-type active regions F1 that protrude from a substrate 402 and extend lengthwise in the first horizontal direction (X direction), and a plurality of nanosheet stacks NSS that face a fin top surface FT of each of the plurality of fin-type active regions F1 while upwardly apart from the plurality of fin-type active regions F1 in the vertical direction (Z direction). For example, the term “nanosheet” refers to a conductive structure that has a cross-section that is substantially perpendicular to a current-flowing direction. The nanosheet includes a nanowire.

A trench T1 is formed in the substrate 402 to define the plurality of fin-type active regions F1, and the trench T1 is filled with a device isolation film 412. The substrate 402 may include a semiconductor, such as Si or Ge, or a compound semiconductor, such as one of SiGe, SiC, GaAs, InAs, InGaAs, or InP. The substrate 402 includes a conductive region, such as an impurity-doped well or an impurity-doped structure. The device isolation film 412 includes one of an oxide film, a nitride film, or a combination thereof.

A plurality of gate lines 460 are disposed on the plurality of fin-type active regions F1. Each of the plurality of gate lines 460 extends lengthwise in a second horizontal direction (Y direction) that intersects with the first horizontal direction (X direction).

In intersection areas between the plurality of fin-type active regions F1 and the plurality of gate lines 460, the plurality of nanosheet stacks NSS are disposed over the fin top surface FT of each of the plurality of fin-type active regions F1. Each of the plurality of nanosheet stacks NSS includes at least one nanosheet that is spaced apart from the fin top surface FT of the fin-type active region F1 in the vertical direction (Z direction) and faces the fin top surface FT of the fin-type active region F1.

In some embodiments, each of the plurality of nanosheet stacks NSS includes a first nanosheet N1, a second nanosheet N2, and a third nanosheet N3 that overlap each other in the vertical direction (Z direction) and are disposed over the fin-type active region F1. Each of the plurality of gate lines 460 surrounds the first nanosheet N1, the second nanosheet N2, and the third nanosheet N3.

Each of the plurality of gate lines 460 include a main gate portion 460M and a plurality of sub-gate portions 460S. The main gate portion 460M extends lengthwise in the second horizontal direction (Y direction) and covers an upper surface of the nanosheet stack NSS. The plurality of sub-gate portions 460S are integrally connected to the main gate portion 460M and are respectively arranged one by one between the first nanosheet N1, the second nanosheet N2, and the third nanosheet N3 and between the first nanosheet N1 and the fin-type active region F1. In the vertical direction (Z direction), the thickness of each of the plurality of sub-gate portions 460S is less than the thickness of the main gate portion 460M.

A plurality of recesses R1 are formed in the fin-type active region F1. A vertical level of a lowermost surface of each of the plurality of recesses R1 is lower than a vertical level of the fin top surface FT of the fin-type active region F1. A plurality of source/drain regions 430 are respectively formed in the plurality of recesses R1. Each of the plurality of source/drain regions 430 is adjacent to at least one gate line 460. Each of the plurality of source/drain regions 430 is in contact with the first nanosheet N1, the second nanosheet N2, and the third nanosheet N3 of the nanosheet stack NSS adjacent thereto.

Each of the plurality of gate lines 460 includes one of a metal, a metal nitride, a metal carbide, or a combination thereof. The metal is one of Ti, W, Ru, Nb, Mo, Hf, Ni, Co, Pt, Yb, Tb, Dy, Er, or Pd. The metal nitride is one of TiN or TaN. The metal carbide includes TiAlC. However, a material that constitutes the plurality of gate lines 460 is not necessarily limited to the examples set forth above. In an embodiment, each of the plurality of gate lines 460 furthers include a gap-fill metal film. The gap-fill metal film is one of a W film or an Al film. In some embodiments, each of the plurality of gate lines 460 includes, but is not necessarily limited to, a TiN film, a stack structure of TiAlC/TiN/W, a stack structure of TiN/TaN/TiAlC/TiN/W, or a stack structure of TiN/TaN/TiN/TiAlC/TiN/W.

A gate dielectric film 452 is interposed between the nanosheet stack NSS and the gate line 460. In some embodiments, the gate dielectric film 452 includes a stack structure of an interface dielectric film and a high-K film. The interface dielectric film includes a low-K material film that has a dielectric constant of about 9 or less, such as a silicon oxide film, a silicon oxynitride film, or a combination thereof. In some embodiments, the interface dielectric film is omitted. The high-K film includes a material that has a dielectric constant that is greater than that of a silicon oxide film. For example, the high-K film may have a dielectric constant of about 10 to about 25. The high-K film includes, but is not necessarily limited to, hafnium oxide.

An upper surface of each of the gate dielectric film 452 and the gate line 460 is covered by a capping insulating pattern 468. The capping insulating pattern 468 is in contact with the upper surface of each of the gate dielectric film 452 and the gate line 460. The capping insulating pattern 468 includes a silicon nitride film.

Both sidewalls of each of the gate line 460 and the capping insulating pattern 468 are covered by an insulating spacer 418. The insulating spacer 418 is disposed on an upper surface of each of the plurality of nanosheet stacks NSS and covers both sidewalls of the main gate portion 460M. The insulating spacer 418 is spaced apart from the gate line 460 with the gate dielectric film 452 interposed therebetween. The insulating spacer 418 includes at least one of \ silicon nitride, silicon oxide, SiCN, SiBN, SiON, SiOCN, SiBCN, SiOC, or a combination thereof.

A plurality of insulating spacers 418 and the plurality of source/drain regions 430 are each covered by an insulating liner 442. Each insulating liner 442 includes one of silicon nitride (SiN), silicon oxide (SiO), SiCN, SiBN, SiON, SiOCN, SiBCN, SiOC, or a combination thereof. In some embodiments, the insulating liner 442 is omitted. An inter-gate dielectric 444 is disposed on the insulating liner 442. The inter-gate dielectric 444 includes one of a silicon nitride film, a silicon oxide film, SiON, SiOCN, or a combination thereof.

Either sidewall of each of the plurality of sub-gate portions 460S is spaced apart from the source/drain region 430 with the gate dielectric film 452 interposed therebetween. The gate dielectric film 452 is interposed between a sub-gate portion 460S of the gate line 460 and each of the first nanosheet N1, the second nanosheet N2, and the third nanosheet N3 and between the sub-gate portion 460S of the gate line 460 and the source/drain region 430.

A plurality of nanosheet transistors are respectively formed on the substrate 402 in the intersection areas between the plurality of fin-type active regions F1 and the plurality of gate lines 460. Each of the first nanosheet N1, the second nanosheet N2, and the third nanosheet N3 of the nanosheet stack NSS has a channel region. In some embodiments, each of the first nanosheet N1, the second nanosheet N2, and the third nanosheet N3 includes one of an Si layer, an SiGe layer, or a combination thereof.

A metal silicide film 472 is formed on an upper surface of each of the plurality of source/drain regions 430. The metal silicide film 472 includes a metal, such as at least one of Ti, W, Ru, Nb, Mo, Hf, Ni, Co, Pt, Yb, Tb, Dy, Er, or Pd. For example, the metal silicide film 472 includes, but is not necessarily limited to, titanium silicide.

The insulating liner 442 and the inter-gate dielectric 444 are formed in the stated order on the plurality of source/drain regions 430 and a plurality of metal silicide films 472. The insulating liner 442 and the inter-gate dielectric 444 constitute a lower insulating structure. In some embodiments, the insulating liner 442 includes, but is not necessarily limited to, one of silicon nitride (SiN), SiCN, SiBN, SiON, SiOCN, SiBCN, or a combination thereof. The inter-gate dielectric 444 includes, but is not necessarily limited to, a silicon oxide film.

A plurality of source/drain contacts CA are respectively disposed on the plurality of source/drain regions 430. Each of the plurality of source/drain contacts CA passes through the inter-gate dielectric 444 and the insulating liner 442 in the vertical direction (Z direction) and is thus in contact with the metal silicide film 472. Each of the plurality of source/drain contacts CA is electrically connected to the source/drain region 430 via the metal silicide film 472. Each of the plurality of source/drain contacts CA is spaced apart from the main gate portion 460M in the first horizontal direction (X direction) with the insulating spacer 418 interposed therebetween.

Each of the plurality of source/drain contacts CA includes a conductive barrier film 474 and a contact plug 476 that are sequentially stacked in the stated order on the metal silicide film 472. The conductive barrier film 474 surrounds and contacts a lower surface and a sidewall of the contact plug 476. In some embodiments, the conductive barrier film 474 includes a metal or a metal nitride. For example, the conductive barrier film 474 includes, but is not necessarily limited to, one of Ti, Ta, W, TiN, TaN, WN, WCN, TiSiN, TaSiN, WSiN, or a combination thereof. The contact plug 476 includes a metal, such as one of molybdenum (Mo), copper (Cu), tungsten (W), cobalt (Co), ruthenium (Ru), manganese (Mn), titanium (Ti), tantalum (Ta), aluminum (Al), or a combination thereof.

An insulating structure 480 is disposed on respective upper surfaces of the plurality of source/drain contacts CA and a plurality of capping insulating patterns 468. The insulating structure 480 includes a lower etch stop film 482 and a lower interlayer dielectric 484 that are sequentially stacked in the stated order on the upper surface of each of the plurality of capping insulating patterns 468. The lower etch stop film 482 includes one of silicon carbide (SiC), SiN, nitrogen-doped silicon carbide (SiC:N), SiOC, AlN, AlON, AlO, AlOC, or a combination thereof. A constituent material of the lower interlayer dielectric 484 is substantially the same as that of the first interlayer dielectric 114 described with reference to FIG. 1A.

As shown in FIG. 5B, in an embodiment, a plurality of source/drain via contacts VA are respectively disposed on the plurality of source/drain contacts CA. Each of the plurality of source/drain via contacts VA passes through the insulating structure 480 and is in contact with a source/drain contact CA. Each of the plurality of source/drain regions 430 is electrically connected to a source/drain via contact VA through the metal silicide film 472 and the source/drain contact CA.

As shown in FIG. 5C, in an embodiment, a gate contact CB is disposed on the gate line 460. The gate contact CB passes through the insulating structure 480 and the gate insulating pattern 468 in the vertical direction (Z direction) and is connected to the gate line 460.

Each of the plurality of source/drain via contacts VA and the gate contact CB includes a contact plug that includes one of molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but a constituent material of the contact plug is not necessarily limited to the examples set forth above. In some embodiments, each of the plurality of source/drain via contacts VA and the gate contact CB further includes a conductive barrier pattern that surrounds a portion of the contact plug. The conductive barrier pattern in each of the plurality of source/drain via contacts VA and the gate contact CB includes a metal or a metal nitride. For example, the conductive barrier pattern includes, but is not necessarily limited to, one of Ti, Ta, W, TiN, TaN, WN, WCN, TiSiN, TaSiN, WSiN, or a combination thereof.

The lower insulating structure LIS and a plurality of lower wiring structures LWS3 that pass through the lower insulating structure LIS in the vertical direction (Z direction) are respectively disposed on the insulating structure 480, the source/drain via contact VA, and the gate contact CB. Detailed configurations of the lower insulating structure LIS and the plurality of lower wiring structures LWS3 are the same as those described with reference to FIGS. 1A to 3B.

The upper insulating structure UIS and a plurality of upper wiring structures UWS3 that pass through the upper insulating structure UIS in the vertical direction (Z direction) are disposed on the lower insulating structure LIS. Detailed configurations of the upper insulating structure UIS and the plurality of upper wiring structures UWS3 are the same as those described with reference to FIGS. 1A to 3B.

According to the integrated circuit device 400 described with reference to FIGS. 5A to 5C, similar to the integrated circuit device 100 described with reference to FIGS. 1A and 1B, because each of the plurality of upper wiring structures UWS3 includes the upper conductive barrier structure 370 that surrounds the upper metal plug 380, the contact resistance between the lower wiring structure LWS3 and the upper wiring structure UWS3 can be reduced, and the reliability of the integrated circuit device 400 is increased by suppressing unintended electromigration of a metal from the upper metal plug 380 and preventing unintended impurity particles, such as oxygen atoms, from penetrating into the upper metal plug 380 from the upper insulating structure UIS.

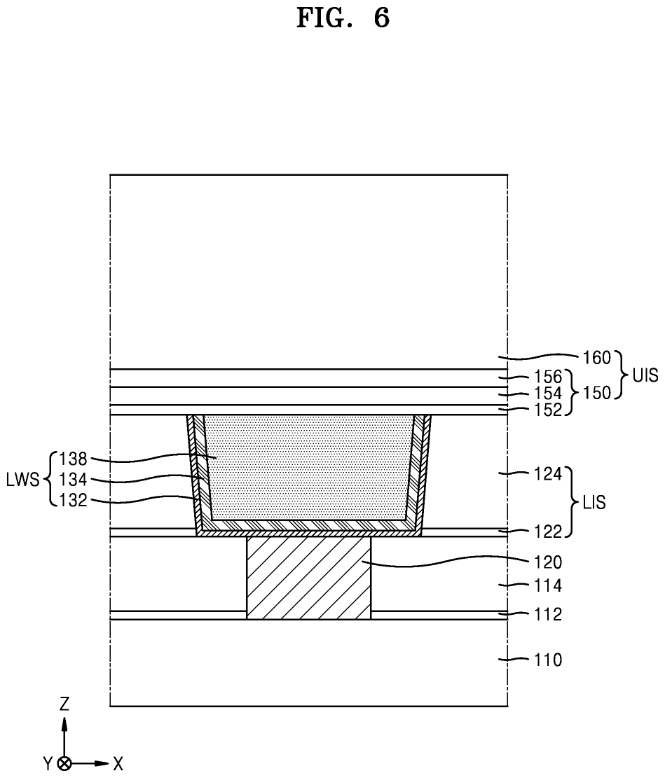

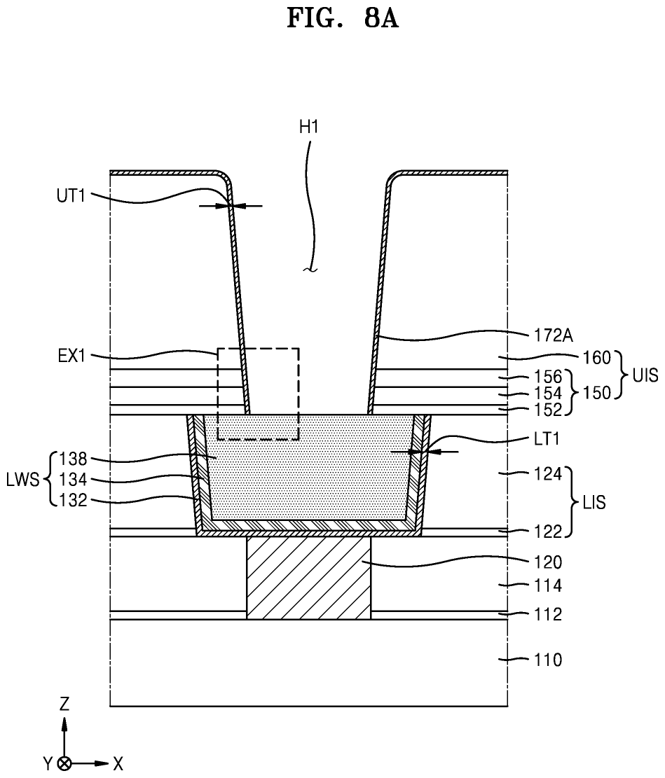

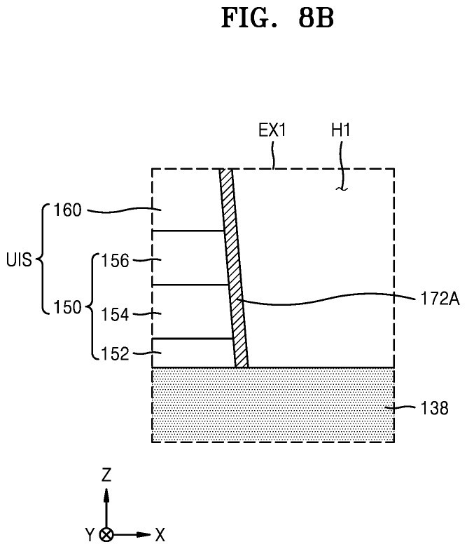

FIGS. 6, 7, 8A, 9A, 10A, 11A, 12A, 13, and 14 are cross-sectional views that respectively illustrate a sequence of processes of a method of fabricating an integrated circuit device, according to some embodiments, and FIGS. 8B, 9B, 10B, 11B, and 12B are enlarged cross-sectional views of regions EX1 of FIGS. 8A, 9A, 10A, 11A, and 12A, respectively. An example of a method of fabricating the integrated circuit device 100 shown in FIGS. 1A and 1B is described with reference to FIGS. 6 to 14. In FIGS. 6 to 14, the same reference numerals as in FIGS. 1A and 1B may respectively denote the same members, and repeated descriptions thereof are omitted.

Referring to FIG. 6, in an embodiment, the first etch stop film 112 and the first interlayer dielectric 114 are formed on the substrate 110, and the conductive structure 120 is formed through the first interlayer dielectric 114 and the first etch stop film 112 to be electrically connected to a conductive region of the substrate 110.

To form the conductive structure 120, an opening is formed by partially etching the first interlayer dielectric 114 and the first interlayer dielectric 114, and then, filling the inside of the opening with conductive materials. The conductive structure 120 is electrically connected with the conductive region formed in the substrate 110. In some embodiments, the conductive structure 120 corresponds to, but is not necessarily limited to, one of a source/drain region, a source/drain contact, a via contact, or a gate contact of a transistor.

The lower insulating structure LIS, which includes the second etch stop film 122 and the second interlayer dielectric 124, and the lower wiring structure LWS, which passes through the lower insulating structure LIS in the vertical direction (Z direction), are formed on the first interlayer dielectric 114. In some embodiments, to form the lower wiring structure LWS, a hole is formed that passes through the lower insulating structure LIS in the vertical direction (Z direction), and then, the first conductive barrier film 132, the second conductive barrier film 134, and the lower metal plug 138 are formed in the stated order in the hole.

The first aluminum-containing insulating film 152, the SiOC film 154, and the second aluminum-containing insulating film 156 are formed in the stated order on the lower insulating structure LIS and the lower wiring structure LWS, thereby forming the multilayered third etch stop film 150. Next, the third interlayer dielectric 160 is formed on the third etch stop film 150. The third etch stop film 150 and the third interlayer dielectric 160 constitute the upper insulating structure UIS.

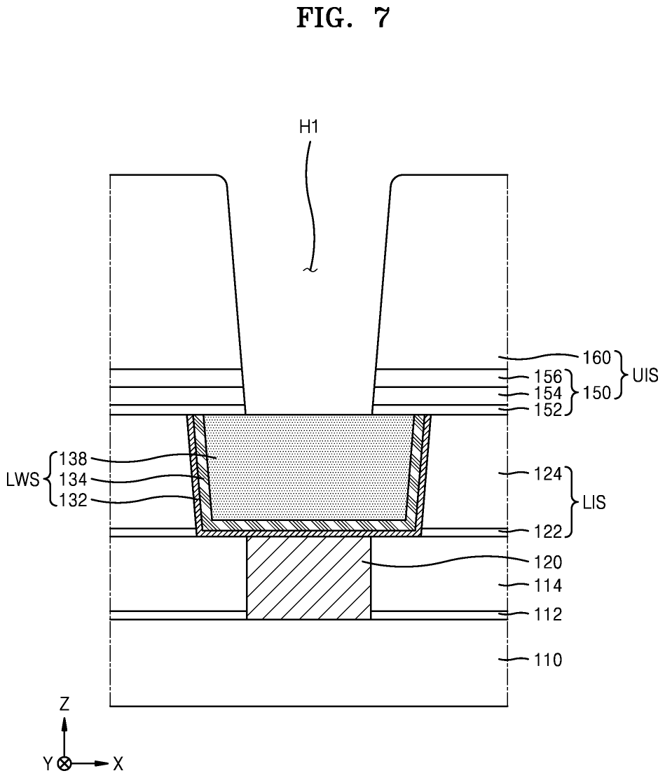

Referring to FIG. 7, in an embodiment, in the resulting product of FIG. 6, portions of the third interlayer dielectric 160 are etched by sequentially using the second aluminum-containing insulating film 156, the SiOC film 154, and the first aluminum-containing insulating film 152 as an etch stop film, thereby forming a hole H1 that passes through the third etch stop film 150 and the third interlayer dielectric 160 in the vertical direction (Z direction) and exposes the upper surface of the lower wiring structure LWS.

In some embodiments, forming the hole H1 includes dry-etching the third interlayer dielectric 160 and the third etch stop film 150 by a plasma etching process or a reactive ion etching (RIE) process. For example, the second aluminum-containing insulating film 156, the SiOC film 154, and the first aluminum-containing insulating film 152 can be sequentially used as an etching end point, and whenever the second aluminum-containing insulating film 156, the SiOC film 154, and the first aluminum-containing insulating film 152 are sequentially exposed, a process of etching a corner portion of the third interlayer dielectric 160 is added such that the corner portion of the third interlayer dielectric 160 that is adjacent to the entrance of the hole H1 is rounded. By doing this, when a reflow process of a metal film, such as a Cu film, is performed to form the upper metal plug 180 in a subsequent process, reflow efficiency is increased.

Referring to FIGS. 8A and 8B, in an embodiment, in the resulting product of FIG. 7, the first TaN film 172A is selectively formed only on exposed surfaces of the upper insulating structure UIS and an exposed surface of the lower wiring structure LWS.

In some embodiments, to form the first TaN film 172A, an ALD process is used. In some embodiments, a thickness UT1 of the first TaN film 172A is less than a thickness LT1 of the first conductive barrier film 132 of the lower wiring structure LWS.

To selectively form the first TaN film 172A only on the exposed surfaces of the upper insulating structure UIS and the exposed upper surface of the lower wiring structure LWS, various processes can be used. For example, in the resulting product of FIG. 7, by selectively surface-treating the exposed upper surface of the lower wiring structure LWS or by selectively forming a passivation layer only on the upper surface of the lower wiring structure LWS, when an ALD process is performed that forms the first conductive barrier film 132, a precursor or reactants supplied onto a substrate are selectively adsorbed only on the exposed surfaces of the upper insulating structure UIS without being adsorbed on the upper surface of the lower wiring structure LWS, thereby selectively forming the first conductive barrier film 132 only on the exposed surfaces of the upper insulating structure UIS.

In the ALD process that forms the first conductive barrier film 132, the precursor or the reactants supplied onto the substrate 110 are not adsorbed on a surface that has a water contact angle that exceeds a certain range, such as a surface having a water contact angle that exceeds about 105 degrees, or a surface that has a water contact angle that exceeds about 110 degrees. Therefore, before the ALD process is performed to form the first conductive barrier film 132, the exposed upper surface of the lower wiring structure LWS is selectively surface-treated, or the passivation layer is selectively formed only on the upper surface of the lower wiring structure LWS, thereby allowing the water contact angle on the exposed surface of the lower wiring structure LWS or on an exposed surface of the passivation layer that covers the lower wiring structure LWS to be greater than the water contact angle on the exposed surfaces of the upper insulating structure UIS.

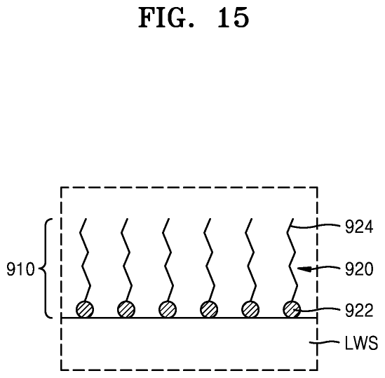

FIG. 15 is a cross-sectional view that illustrates, in a process described with reference to FIGS. 8A and 8B, an example of selectively forming the first TaN film 172A only on the exposed surfaces of the upper insulating structure UIS and the exposed upper surface of the lower wiring structure LWS.

Referring to FIG. 15, in an embodiment, before the first TaN film 172A is formed, a passivation layer 910 is selectively formed only on the exposed surfaces of the upper insulating structure UIS and the exposed upper surface of the lower wiring structure LWS. Next, as shown in FIGS. 8A and 8B, the first TaN film 172A is selectively formed only on the exposed surfaces of the upper insulating structure and an exposed surface of the passivation layer 910.

In FIG. 15, a portion marked as the lower wiring structure LWS corresponds to a film that has a conductive metal surface or a conductive metallic surface. In an embodiment, the lower wiring structure LWS shown in FIG. 15 corresponds to the lower metal plug 138. However, embodiments of the inventive concept are not necessarily limited thereto. In some embodiments, the lower wiring structure LWS shown in FIG. 15 includes, but is not necessarily limited to, one of Cu, Co, W, Ru, Ir, Al, Ni, Nb, Fe, TaN, TiN, or a combination thereof.

As shown in FIG. 15, to selectively form the passivation layer 910 only on the lower wiring structure LWS, the passivation layer 910 includes a self-assembled monolayer (SAM) that is formed on the lower wiring structure LWS. In some embodiments, the passivation layer 910 includes a resulting product in which a plurality of molecules 920, each having an anchoring group 922 and a hydrophobic or inactive tail 924, are self-assembled on the lower wiring structure LWS, where the anchoring group 922 is anchored on the lower wiring structure LWS. Each of the plurality of molecules 920 includes an amphiphilic molecule in which a head group that constitutes the anchoring group 922 has a reversible affinity with respect to the lower wiring structure LWS. In some embodiments, the passivation layer 910 includes a polymer.

In some embodiments, to form the passivation layer 910 on the lower wiring structure LWS in a self-assembled manner, an adsorption inhibitor is supplied onto the substrate 110. For example, the adsorption inhibitor includes, but is not necessarily limited to, one of an alkyl halide that has a C1 to C20 alkyl group and is represented by CₙH₂ₙ₊₁ X, where X is F, Cl, Br, or I; an alkanethiol that has a C1 to C20 alkyl group; a silane derivative; or a combination thereof. The alkanethiol includes, but is not necessarily limited to, one of dodecanethiol or octadecanethiol. The silane derivative includes, but is not necessarily limited to, one of tris(dimethylamino)octylsilane, tris(dimethylamino)octadecylsilane, dodecyltrichlorosilane, octadecyltrichlorosilane, octadecylthiethoxy-silane, octadecyltrimethylsilane, (1,1,2,2-perfluorodecyl)trichlorosilane, trichloro(1,1,2,2-perflrorooctyl)silane, (trideca-fluoro-1,1,2,2-tetrahydrooctyl)trichlorosilane, (tridecafluoro-1,1,2,2-tetrahydro-octyl)triethoxysilane, (tridecafluoro-1,1,2,2-tetrahydrooctyl)methyldichlorosilane, (tridecafluoro-1,1,2,2-tetrahydrooctyl)dimethylchlorosilane, (heptadecafluoro-1,1,2,2-tetrahydrodecyl)trichlorosilane, or a combination thereof.

As described above, after the passivation layer 910 is formed on the lower wiring structure LWS by supplying the adsorption inhibitor onto the substrate 110, a purge process is performed that supplies a purge gas onto the substrate 110 that removes an excess of the adsorption inhibitor that remains on the substrate 110.

As shown in FIG. 15, when an ALD process that forms the first TaN film 172A is performed after the passivation layer 910 has been formed on the lower wiring structure LWS, a precursor or reactants used to form the first TaN film 172A are not adsorbed on the passivation layer 910 and are selectively adsorbed only on the exposed surfaces of the upper insulating structure UIS.

Referring again to FIGS. 8A and 8B, to form the first TaN film 172A by an ALD process, one of pentakis(dimethylamido)tantalum (PDMAT), (tert-butylimido)tris(diethylamido)tantalum (TBTDET), tantalum pentachloride (TaCl₅), tantalum pentafluoride (TaF₅), pentakis(diethylamide)tantalum (PDEAT), pentakis(ethylmethylamino)tantalum (PEMAT), or a combination thereof, is used as a Ta precursor, but embodiments of the inventive concept are not necessarily limited thereto.

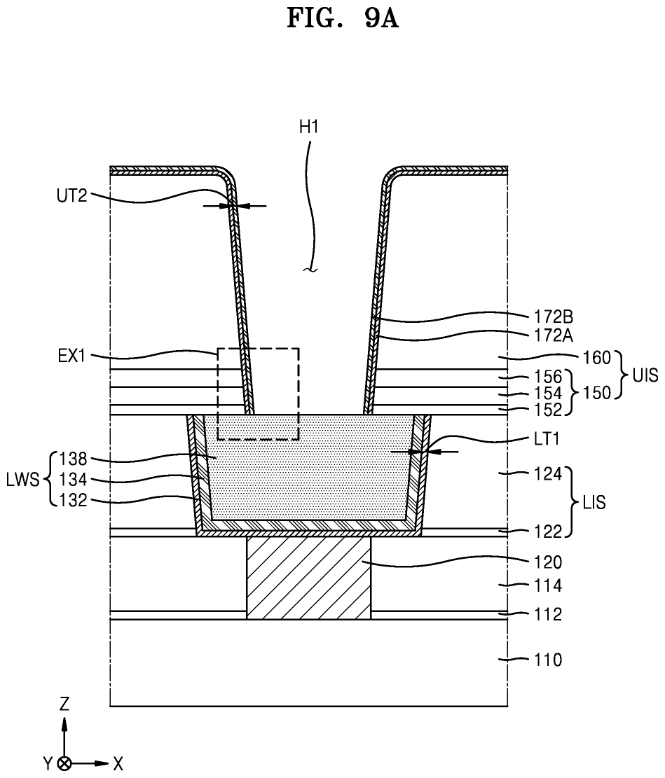

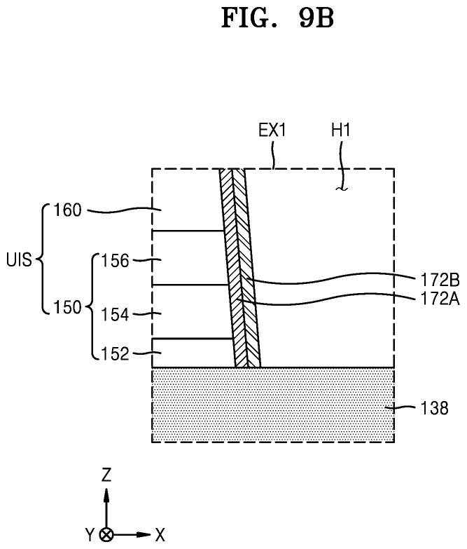

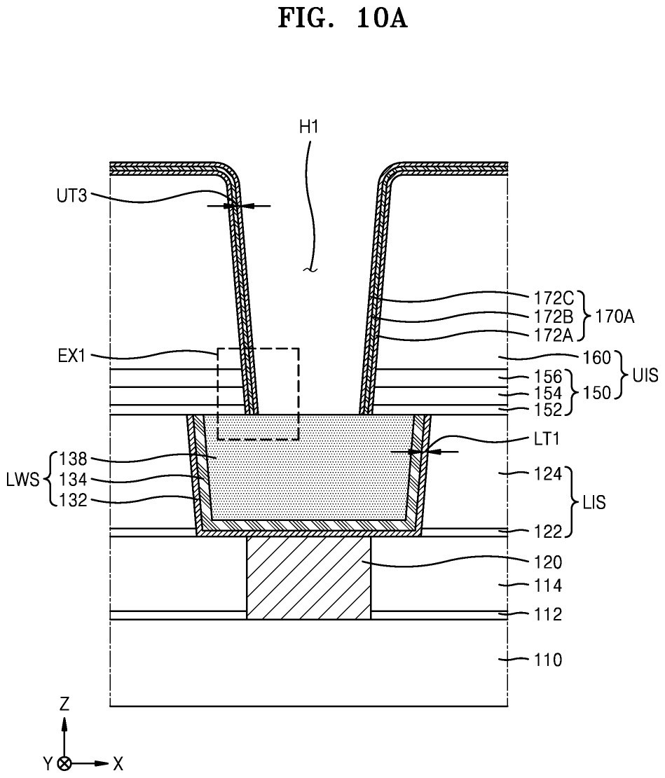

Referring to FIGS. 9A and 9B, in an embodiment, in the resulting product of FIGS. 8A and 8B, the Ru film 172B is selectively formed only on exposed surfaces of the first TaN film 172A. In some embodiments, a thickness UT2 of the Ru film 172B is less than the thickness LT1 of the first conductive barrier film 132 of the lower wiring structure LWS.

In some embodiments, to form the Ru film 172B, as described with reference to FIGS. 9A, 0B, and 15, an ALD process is performed after the upper surface of the lower wiring structure LWS has been selectively surface-treated or the passivation layer 910 has been selectively formed only on the upper surface of the lower wiring structure LWS.

To form the Ru film 172B by an ALD process, one of C₁₄H₁₈Ru [(ethylbenzene)(cyclohexadiene)ruthenium (abbreviated to EBCHRu)], C₁₆H₂₂Ru [(η6-1-isopropyl-4-methylbenzene)(η4-cyclohexa-1,3-diene)ruthenium], Ru(EtCp)₂(bis(ethylcyclopentadienyl)ruthenium(II)), or a combination thereof, is used as an Ru precursor, but embodiments of the inventive concept are not necessarily limited thereto.

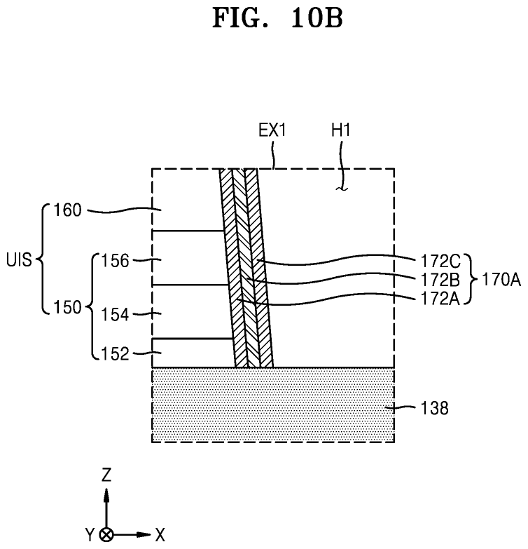

Referring to FIGS. 10A and 10B, in an embodiment, in the resulting product of FIGS. 9A and 9B, the second TaN film 172C is selectively formed only on exposed surfaces of the Ru film 172B. In some embodiments, a thickness UT3 of the second TaN film 172C is less than the thickness LT1 of the first conductive barrier film 132 of the lower wiring structure LWS.

In some embodiments, to form the second TaN film 172C, as described with reference to FIGS. 10A, 10B, and 15, an ALD process is performed after the upper surface of the lower wiring structure LWS has been selectively surface-treated or the passivation layer 910 has been selectively formed only on the upper surface of the lower wiring structure LWS. A process of forming the second TaN film 172C is substantially the same as a process of forming the first TaN film 172A as described with reference to FIGS. 8A and 8B.

After the first multilayered film 170A, which includes the first TaN film 172A, the Ru film 172B, and the second TaN film 172C, is formed, the passivation layer 910 shown in FIG. 15 may 15 may be removed. In some embodiments, to remove the passivation layer 910, hydrogen plasma is used, but embodiments of the inventive concept are not necessarily limited thereto.

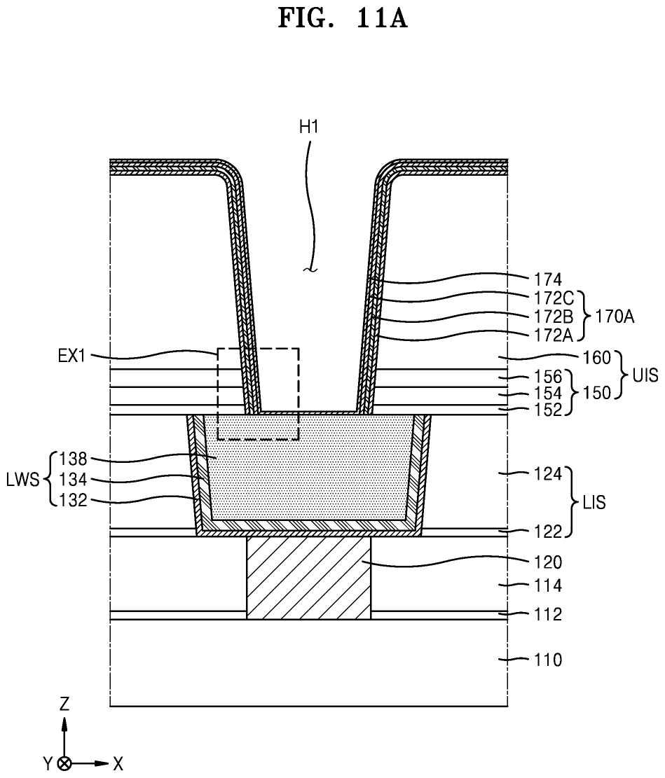

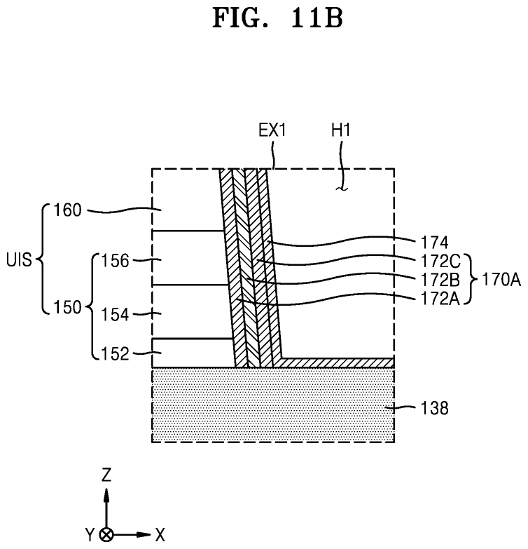

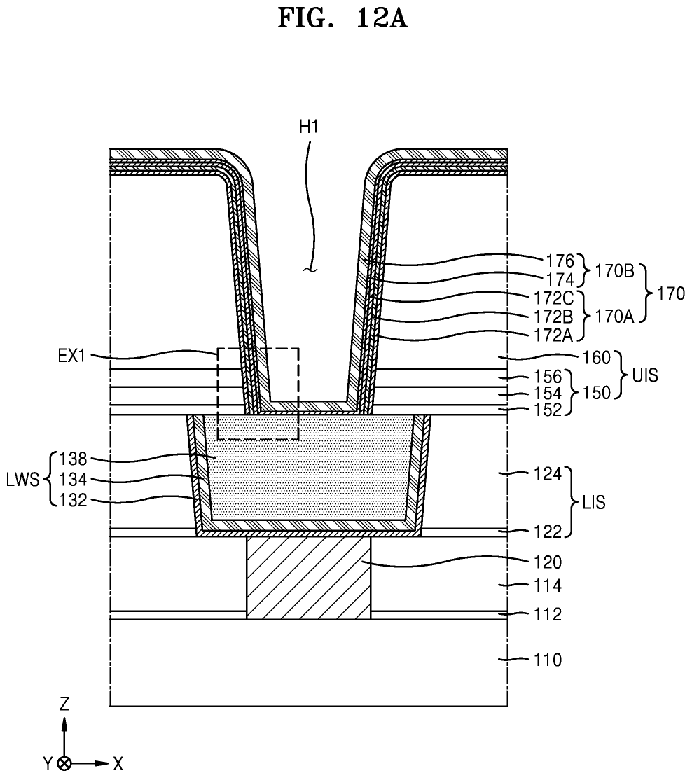

Referring to FIGS. 11A and 11B, in an embodiment, in the resulting product of FIGS. 10A and 10B, the third TaN film 174 is formed that conformally covers exposed surfaces of the first multilayered film 170A and the upper surface of the lower wiring structure LWS. In some embodiments, a PVD process is used to form the third TaN film 174.

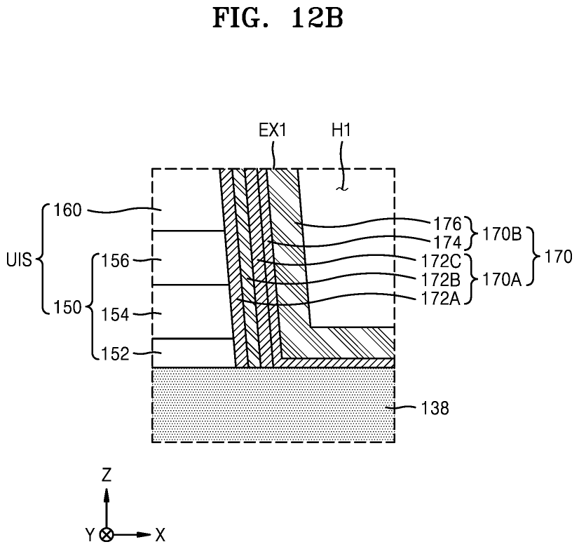

Referring to FIGS. 12A and 12B, in an embodiment, the Co film 176 is formed on the resulting product of FIGS. 11A and 11B. In some embodiments, a chemical vapor deposition (CVD) process is performed to form the Co film 176. The third TaN film 174 and the Co film 176 constitute the second multilayered film 170B.

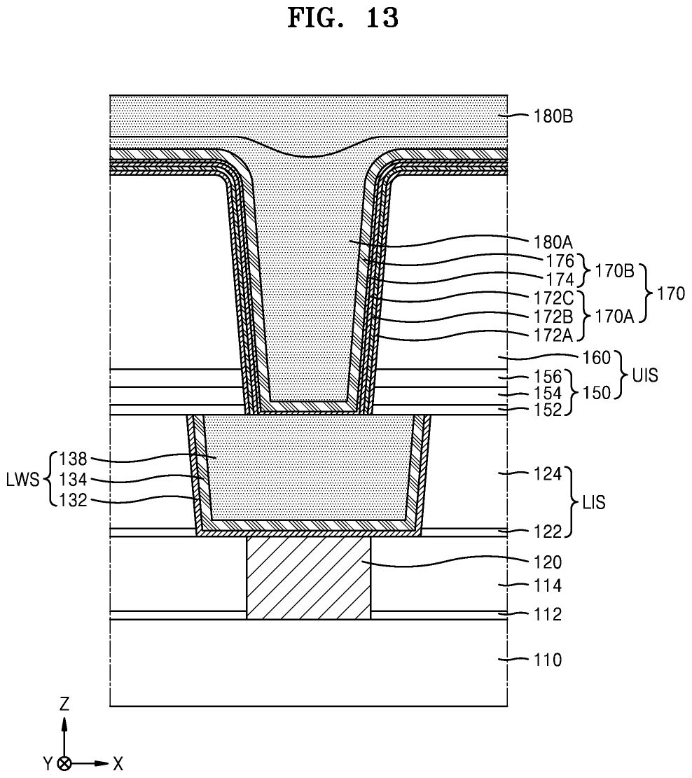

Referring to FIG. 13, in an embodiment, in the resulting product of FIGS. 12A and 12B, a first metal film 180A that fill the hole H1 is formed by a CVD process, and then, a second metal film 180B that covers the first metal film 180A is formed outside the hole H1 by a PVD process. Next, the resulting product, in which the second metal film 180B is formed, is annealed, thereby growing metal grains that are included in the first metal film 180A and the second metal film 180B.

The first metal film 180A and the second metal film 180B each include a same metal. For example, each of the first metal film 180A and the second metal film 180B includes Cu. In some embodiments, to form the first metal film 180A, a local Cu film that fills only a portion of the hole H1 is formed by a CVD process, and then, a process of reflowing the local Cu film is performed at least twice, for example, three times. The process of reflowing the local Cu film is performed at a temperature in a range of about 100° C. to about 500° C., such as a temperature range of about 150° C. to about 250° C.

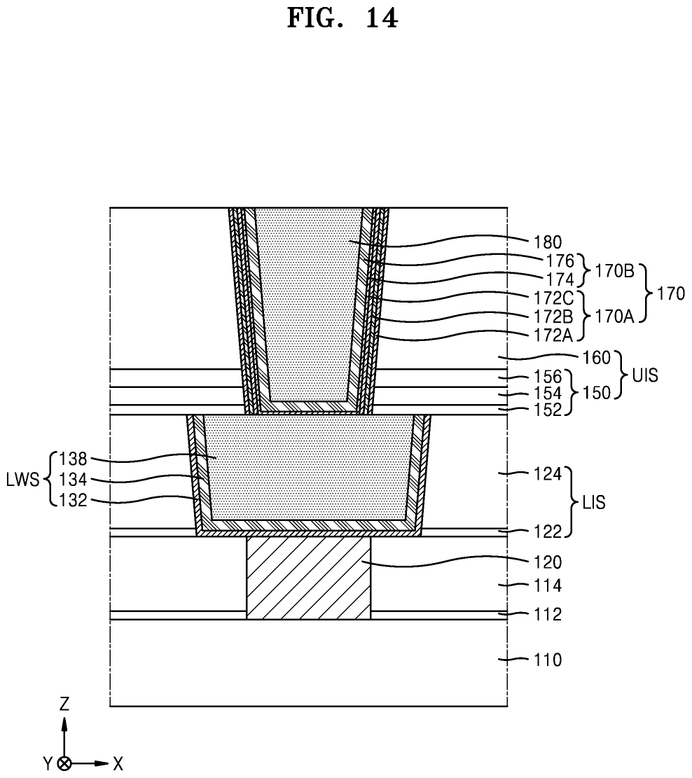

Referring to FIG. 14, in an embodiment, by performing a chemical mechanical polishing (CMP) process on the resulting product of FIG. 13, the second metal film 180B is removed, and a portion of the first metal film 180A, and respective portions of the first multilayered film 170A and the second multilayered film 170B that cover an upper surface of the third interlayer dielectric 160 are removed to expose the third interlayer dielectric 160. A portion of the first metal film 180A that is left in the hole H1 remains as the upper metal plug 180. In a resulting product in which the upper metal plug 180 remains over the substrate 110 through the CMP process, the height of the third interlayer dielectric 160 in the vertical direction (Z direction) is less than that of the third interlayer dielectric 160 in the resulting product of FIG. 13.

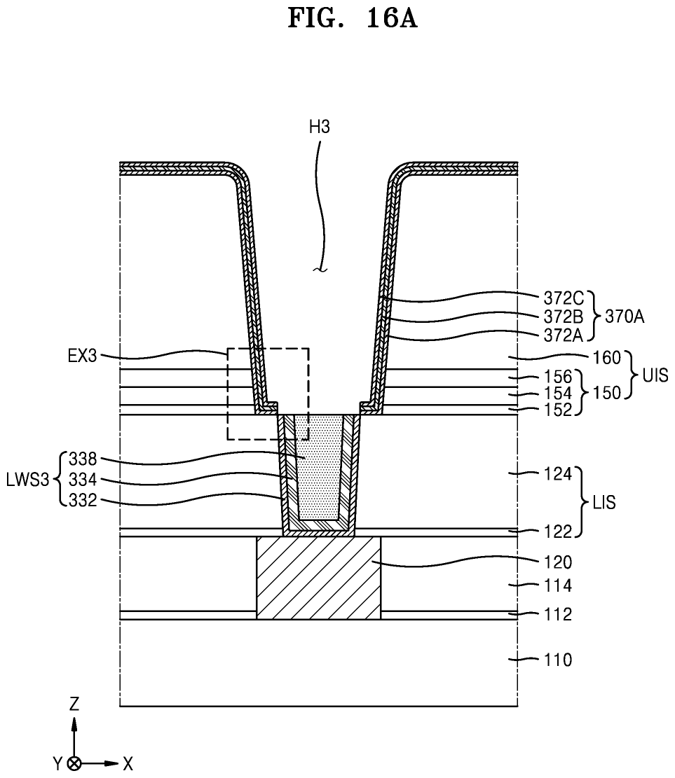

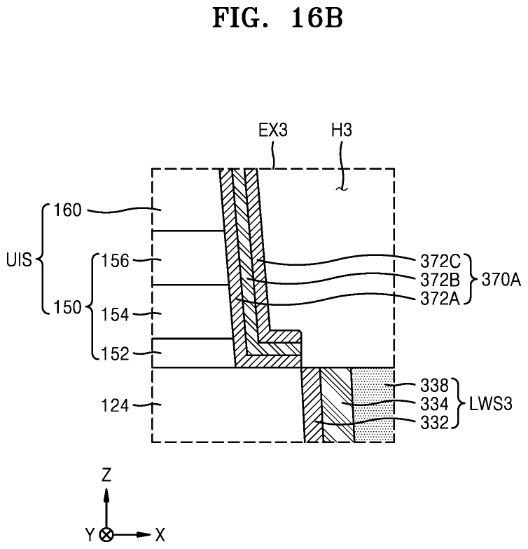

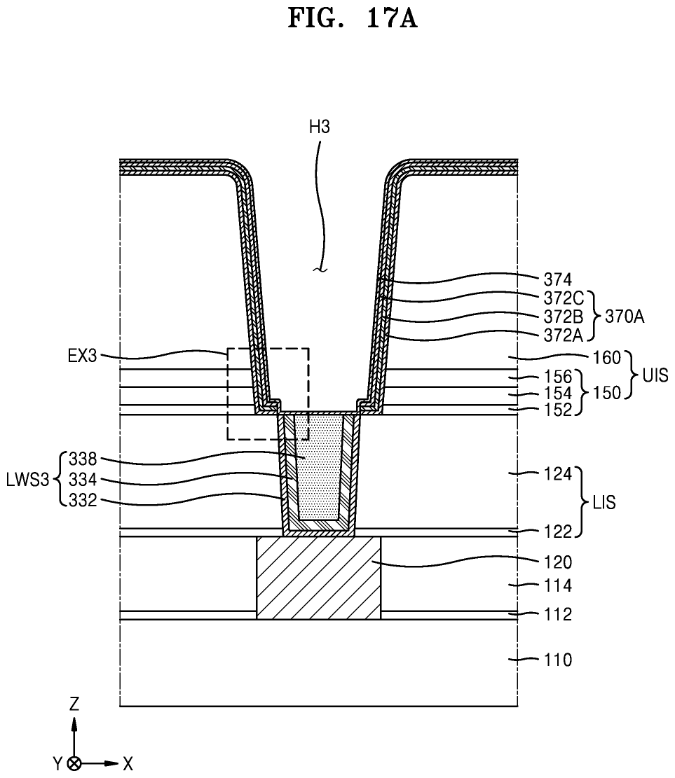

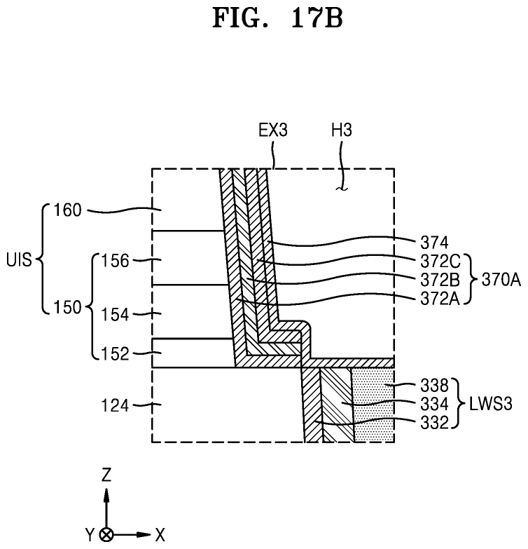

FIGS. 16A and 17A are cross-sectional views that respectively illustrate processes of a method of fabricating an integrated circuit device, according to some embodiments, and FIGS. 16B and 17B are enlarged cross-sectional views of regions EX3 of FIGS. 16A and 17A, respectively. An example of a method of fabricating the integrated circuit device 300A shown in FIGS. 3A and 3B is described with reference to FIGS. 16A to 17B. In FIGS. 16A to 17B, the same reference numerals as in FIGS. 1A and 14 may respectively denote the same members, and repeated descriptions thereof are omitted.

Referring to FIGS. 16A and 16B, in an embodiment, processes similar to those described with reference to FIGS. 6 and 7 are performed. However, in a process described with reference to FIG. 6, the lower wiring structure LWS3 is formed instead of the lower wiring structure LWS, and in a process described with reference to FIG. 7, a hole H3 is formed that passes through the third etch stop film 150 and the third interlayer dielectric 160 in the vertical direction (Z direction) and exposes the upper surface of the lower wiring structure LWS3. The hole H3 exposes the upper surface of the lower wiring structure LWS3, surfaces of the upper insulating structure UIS, and a portion of the upper surface of the second interlayer dielectric 124 of the lower insulating structure LIS.

Next, processes similar to those described with reference to FIGS. 8A to 10B are performed. However, in an embodiment, the first multilayered film 370A is formed instead of the first multilayered film 170A. The first multilayered film 370A is selectively formed only on the respective surfaces of the upper insulating structure UIS and the lower insulating structure LIS that are exposed by the hole H3.

Referring to FIGS. 17A and 17B, in an embodiment, the third TaN film 374 is formed by a method similar to a process that forms the third TaN film 174 as described with reference to FIGS. 11A and 11B.

Next, processes similar to those described with reference to FIGS. 12A to 14 are performed on the resulting product of FIGS. 17A and 17B, thereby fabricating the integrated circuit device 300A shown in FIGS. 3A and 3B.

Heretofore, while embodiments of methods of respectively fabricating the integrated circuit device 100 shown in FIGS. 1A and 1B and the integrated circuit device 300A shown in FIGS. 3A and 3B have been described with reference to FIGS. 6 to 17B, it will be understood by those of ordinary skill in the art that various modifications and changes to embodiments described with reference to FIGS. 6 to 17B can be made without departing from the spirit and scope of the inventive concept, and the integrated circuit device 200 shown in FIG. 2, the integrated circuit device 300B shown in FIG. 4, the integrated circuit device 400 shown in FIGS. 5A to 5C, and integrated circuit devices that have various structures modified and changed therefrom can be fabricated.

While embodiments of the inventive concept have been particularly shown and described with reference to drawings thereof, it will be understood that various changes in form and details may be made therein without departing from the spirit and scope of the following claims.

What is claimed is:

1. An integrated circuit device, comprising:
a lower insulating structure disposed over a substrate;
a lower wiring structure that passes through the lower insulating structure in a vertical direction;
an upper insulating structure disposed on the lower insulating structure; and
an upper wiring structure that passes through the upper insulating structure in the vertical direction and that contacts the lower wiring structure,
wherein the upper wiring structure comprises an upper metal plug and an upper conductive barrier structure, and the upper conductive barrier structure surrounds a sidewall and a lower surface of the upper metal plug, and
wherein the upper conductive barrier structure comprises a first barrier portion that faces a sidewall of the upper insulating structure, and a second barrier portion interposed between the lower wiring structure and the upper metal plug, and the first barrier portion and the second barrier portion have different structures from each other.

2. The integrated circuit device of claim 1, wherein
each of the first barrier portion and the second barrier portion of the upper conductive barrier structure has a multilayered structure, and
a thickness of the first barrier portion is greater than a thickness of the second barrier portion.

3. The integrated circuit device of claim 1, wherein, in the upper conductive barrier structure,
the first barrier portion comprises a first multilayered film that includes at least three conductive films that differ from each other and are sequentially stacked from the upper insulating structure toward the upper metal plug, and
the second barrier portion comprises a second multilayered film that includes two conductive films that differ from each other and are sequentially stacked from the lower wiring structure toward the upper metal plug.

4. The integrated circuit device of claim 1, wherein, in the upper conductive barrier structure, the first barrier portion and the second barrier portion each include two conductive films that differ from each other.

5. The integrated circuit device of claim 1, wherein
the first barrier portion of the upper conductive barrier structure includes a first metal film and a second metal film that are spaced apart from each other, and
the first metal film and the second metal film include different metals from each other.

6. The integrated circuit device of claim 1, wherein
the first barrier portion of the upper conductive barrier structure includes an Ru film and a Co film that are spaced apart from each other, and
the Co film is closer to the upper metal plug than the Ru film.

7. The integrated circuit device of claim 1, wherein, in the upper conductive barrier structure,
the first barrier portion includes a first metal nitride film, a first metal film, a second metal nitride film, a portion of a third metal nitride film, and a portion of a second metal film that are stacked in the stated order on the sidewall of the upper insulating structure, and
the second barrier portion includes another portion of the third metal nitride film and another portion of the second metal film that are stacked in the stated order on an upper surface of the lower wiring structure.

8. The integrated circuit device of claim 1, wherein,
in a first horizontal direction that is parallel to a main surface of the substrate, a width of the lower wiring structure is greater than a width of the upper wiring structure, and
the first barrier portion of the upper conductive barrier structure is in contact with the upper insulating structure but not the lower insulating structure.

9. The integrated circuit device of claim 1, wherein,
in a first horizontal direction that is parallel to a main surface of the substrate, a width of the lower wiring structure is less than a width of the upper wiring structure, and
the first barrier portion of the upper conductive barrier structure is in contact with each of the lower insulating structure and the upper insulating structure.

10. The integrated circuit device of claim 1, wherein
the lower wiring structure includes a lower metal plug and a lower conductive barrier structure, and the lower conductive barrier structure surrounds a sidewall and a lower surface of the lower wiring structure,
the upper wiring structure includes a first multilayered film and a second multilayered film that are stacked in the stated order from the upper insulating structure toward the upper metal plug, and the first multilayered film and the second multilayered film have different stacked structures from each other,
the first multilayered film is in contact with each of the lower insulating structure and the upper insulating structure, and
the second multilayered film is not in contact with the lower insulating structure and the upper insulating structure and is in contact with an upper surface of each of the lower metal plug and the lower conductive barrier structure.

11. An integrated circuit device, comprising:
a lower insulating structure disposed over a substrate;
a lower wiring structure that passes through the lower insulating structure in a vertical direction;
an upper insulating structure disposed on the lower insulating structure; and
an upper wiring structure that includes an upper metal plug that passes through the upper insulating structure in the vertical direction, and an upper conductive barrier structure that surrounds a sidewall and a lower surface of the upper metal plug,
wherein the upper conductive barrier structure comprises:
a first barrier portion that is arranged between the upper metal plug and the upper insulating structure and contacts each of the upper metal plug and the upper insulating structure, and that includes a plurality of metal nitride films and a plurality of metal films, wherein the plurality of metal films include different metals from each other; and
a second barrier portion that is arranged between the upper metal plug and the lower wiring structure and contacts each of the upper metal plug and the lower wiring structure, wherein the second barrier portion has a different structure from the first barrier portion.

12. The integrated circuit device of claim 11, wherein a metal nitride film of the plurality of metal nitride films, and a metal film of the plurality of metal films each include a portion interposed between the upper metal plug and the upper insulating structure and a portion interposed between the upper metal plug and the lower wiring structure, such that the metal nitride film and the metal film are commonly includes in the first barrier portion and the second barrier portion.

13. The integrated circuit device of claim 11, wherein a thickness of the first barrier portion is greater than a thickness of the second barrier portion.

14. The integrated circuit device of claim 11, wherein
each of the first barrier portion and the second barrier portion includes one TaN film and one Co film, and
the first barrier portion further includes an Ru film, the second barrier portion does not include an Ru film, and the Ru film of the first barrier portion is spaced apart from the one Co film with the one TaN film interposed therebetween.

15. The integrated circuit device of claim 11, wherein
the upper wiring structure includes a first multilayered film and a second multilayered film that are stacked in the stated order from the upper insulating structure toward the upper metal plug, wherein the first multilayered film and the second multilayered film have different stacked structures from each other,
the first multilayered film is in contact with each of the lower insulating structure and the upper insulating structure, and
the second multilayered film is not in contact with the lower insulating structure and the upper insulating structure and is in contact with each of a surface of the first multilayered film and an upper surface of the lower wiring structure.

16. The integrated circuit device of claim 11, wherein the upper conductive barrier structure comprises:
a first multilayered film that extends along a first sidewall of the upper insulating structure, wherein the first sidewall faces the upper wiring structure; and
a second multilayered film that is disposed over the first sidewall of the upper insulating structure and extends along the first multilayered film, and that is disposed on the lower wiring structure and extends along an upper surface of the lower wiring structure, wherein the second multilayered film is contact with each of the first multilayered film and the upper surface of the lower wiring structure,
and wherein the first multilayered film and the second multilayered film have different stacked structures from each other.

17. The integrated circuit device of claim 16, wherein
the first multilayered film includes a first TaN film, an Ru film, and a second TaN film that are stacked in the stated order from the upper insulating structure toward the upper metal plug, and
the second multilayered film includes a third TaN film and a Co film that are stacked in the stated order from each of the first multilayered film and the lower wiring structure toward the upper metal plug.

18. The integrated circuit device of claim 11, wherein the upper insulating structure comprises:
an etch stop film that includes a first aluminum oxide film that covers an upper surface of the lower insulating structure, an SiOC film that covers an upper surface of the first aluminum oxide film, and a second aluminum oxide film that covers an upper surface of the SiOC film; and
an interlayer dielectric that covers the etch stop film,
wherein the first barrier portion of the upper conductive barrier structure is in contact with each of the etch stop film and the interlayer dielectric.

19. The integrated circuit device of claim 11, wherein the upper insulating structure comprises:
an etch stop film that includes an aluminum nitride film that covers an upper surface of the lower insulating structure and an SiOC film that covers an upper surface of the aluminum nitride film; and
an interlayer dielectric that covers the etch stop film,
wherein the first barrier portion of the upper conductive barrier structure is in contact with each of the etch stop film and the interlayer dielectric.

20. An integrated circuit device, comprising:
a lower insulating structure disposed over a substrate;
a lower wiring structure that passes through the lower insulating structure in a vertical direction;
an upper insulating structure disposed on the lower insulating structure and the lower wiring structure and that includes an etch stop film and an interlayer dielectric that covers an upper surface of the etch stop film, wherein the etch stop film has a multilayered structure that includes a plurality of insulating films that include different materials from each other; and
an upper wiring structure that includes an upper metal plug that passes through the upper insulating structure in the vertical direction, and an upper conductive barrier structure that surrounds a sidewall and a lower surface of the upper metal plug,
wherein the upper conductive barrier structure comprises:
a first multilayered film that extends along a first sidewall of the upper insulating structure and includes a first TaN film, an Ru film, and a second TaN film that are sequentially stacked in the stated order from the first sidewall of the upper insulating structure toward the upper metal plug, wherein the first sidewall faces the upper wiring structure; and
a second multilayered film that is disposed over the first sidewall of the upper insulating structure and extends along the first multilayered film, and that is disposed on the lower wiring structure and extends along an upper surface of the lower wiring structure, wherein the second multilayered film is spaced apart from the first sidewall of the upper insulating structure with the first multilayered film interposed therebetween and includes a third TaN film and a Co film that are sequentially stacked in the stated order from each of a surface of the first multilayered film and the upper surface of the lower wiring structure toward the upper metal plug.
